(19) United States
(12) Patent Application Publication
(10) Pub. No.: US 2025/0105584 A1
(43) Pub. Date: Mar. 27, 2025

(54) SEMICONDUCTOR LIGHT EMITTING DEVICE

(71) Applicant: ROHM CO., LTD., Kyoto (JP)

(72) Inventors: Okimoto KONDO, Kyoto (JP); Yuya HASEGAWA, Kyoto (JP)

(21) Appl. No.: 18/882,846

(22) Filed: Sep. 12, 2024

(30) Foreign Application Priority Data
Sep. 25, 2023 (JP) 2023-160240

(51) Int. Cl. H01S 5/02255; H01S 5/02234; H01S 5/183

(52) U.S. Cl. CPC H01S 5/02255; H01S 5/02234; H01S 5/183

(57) ABSTRACT

A semiconductor light emitting device includes: a surface emitting laser element including an element front surface and configured to emit laser light from the element front surface; an element container including a bottom wall where the surface emitting laser element is arranged and a peripheral wall surrounding the surface emitting laser element when viewed from a direction perpendicular to the element front surface, the bottom wall and the peripheral wall constituting a containing space which contains the surface emitting laser element and is open on a same side as the element front surface; a diffusion layer covering the element front surface in the containing space and including a diffusion material; and a reflector covering at least one selected from the group of the bottom wall and the peripheral wall in the containing space and made of a resin material having a higher reflectivity than the diffusion layer.

### CROSS-REFERENCE TO RELATED APPLICATION

This application is based upon and claims the benefit of priority from Japanese Patent Application No. 2023-160240, filed on Sep. 25, 2023, the entire contents of which are incorporated herein by reference.

### TECHNICAL FIELD

The present disclosure relates to a semiconductor light emitting device.

### BACKGROUND

In the related art, semiconductor light emitting devices equipped with light emitting diodes (LEDs) serving as light sources have been known as light source devices mounted in various electronic apparatuses.

### BRIEF DESCRIPTION OF DRAWINGS

The accompanying drawings, which are incorporated in and constitute a part of the specification, illustrate embodiments of the present disclosure.

FIG. 1 is a schematic perspective view of a semiconductor light emitting device according to a first embodiment of the present disclosure.

FIG. 2 is a schematic plan view of an interior of the semiconductor light emitting device of FIG. 1.

FIG. 3 is a schematic cross-sectional view of the semiconductor light emitting device taken along line F3-F3 in FIG. 2.

FIG. 4 is a schematic plan view of the interior of the semiconductor light emitting device of FIG. 2 to which a reflector is added.

FIG. 5 is a schematic plan view of a semiconductor light emitting device according to a second embodiment of the present disclosure.

FIG. 6 is a schematic cross-sectional view of the semiconductor light emitting device taken along line F6-F6 in FIG. 5.

FIG. 7 is a schematic cross-sectional view of the semiconductor light emitting device taken along line F7-F7 in FIG. 5.

FIG. 8 is a schematic plan view of a semiconductor light emitting device according to a third embodiment of the present disclosure.

FIG. 9 is a schematic cross-sectional view of the semiconductor light emitting device taken along line F9-F9 in FIG. 8.

FIG. 10 is a schematic cross-sectional view of a semiconductor light emitting device according to a fourth embodiment of the present disclosure.

FIG. 11 is a schematic plan view of a semiconductor light emitting device according to a modification.

FIG. 12 is a schematic cross-sectional view of a semiconductor light emitting device according to a modification.

FIG. 13 is a schematic cross-sectional view of a semiconductor light emitting device according to a modification.

FIG. 14 is a schematic cross-sectional view of a semiconductor light emitting device according to a modification.

FIG. 15 is a schematic plan view of a semiconductor light emitting device according to a modification.

FIG. 16 is a schematic cross-sectional view of the semiconductor light emitting device taken along line F16-F16 in FIG. 15.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, some embodiments of a semiconductor light emitting device according to the present disclosure will be described with reference to the accompanying drawings. It should be noted that, for simplicity and clarity of explanation, constituent elements shown in the drawings are not necessarily drawn to scale. Further, in order to facilitate understanding, hatching lines may be omitted in cross-sectional views. The accompanying drawings merely illustrate embodiments of the present disclosure and should not be considered as limiting the present disclosure.

The following detailed description includes devices, systems, and methods embodying exemplary embodiments of the present disclosure. This detailed description is for illustrative purposes only and is not intended to limit the embodiments of the present disclosure or the applications and uses of such embodiments.

The expression “at least one” as used in the present disclosure means “one or more” of desired options. As an example, in a case where there are two options, the expression “at least one” as used in the present disclosure means “only one option” or “both of the two options.” As another example, in a case where there are three or more options, the expression “at least one” as used in the present disclosure means “only one option” or “any combination of two or more options.”

“A length (thickness, dimension) of A is equal to a length (thickness, dimension) of B” or “a length (thickness, dimension) of A and a length (thickness, dimension) of B are equal to each other” as used in the present disclosure also includes a relationship in which a difference between a length (thickness, dimension) of A and a length (thickness, dimension) of B is, for example, within 10% of the length (thickness, dimension) of A.

### First Embodiment

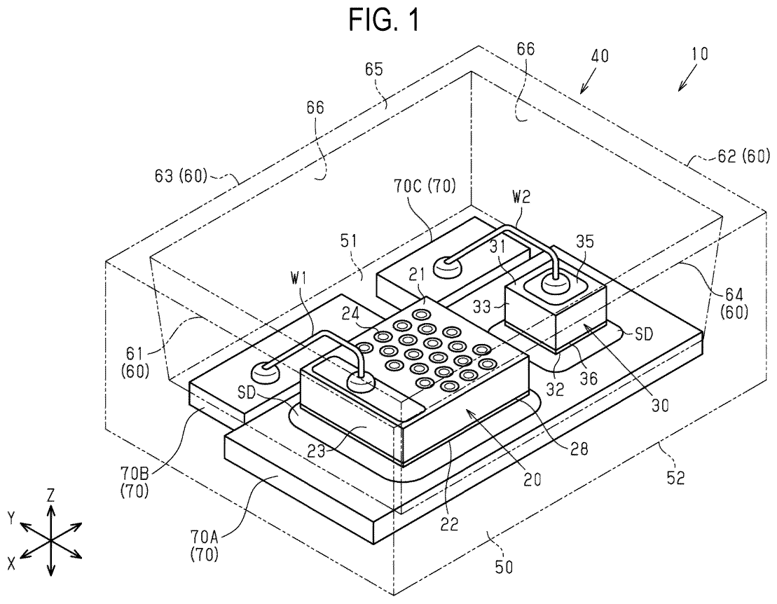

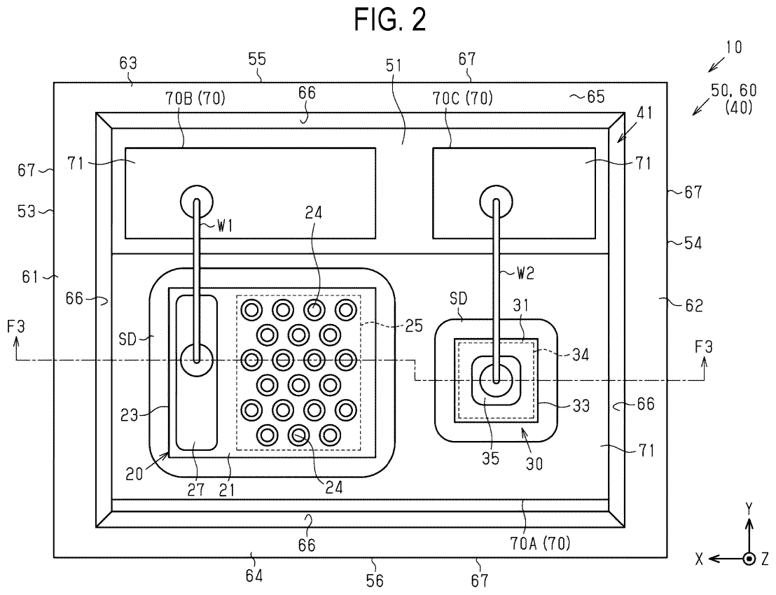

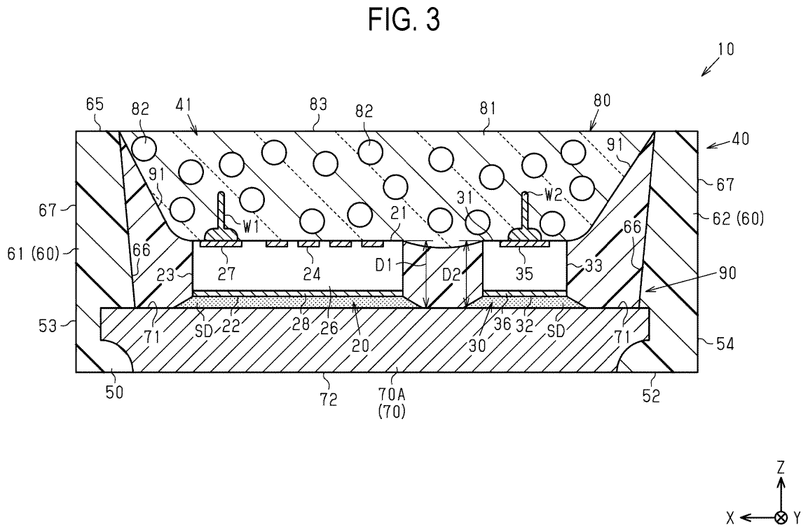

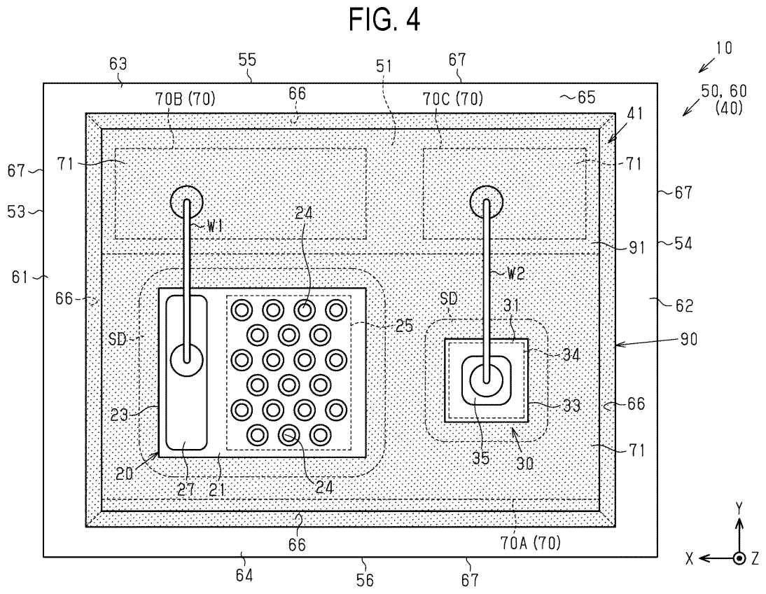

A semiconductor light emitting device 10 according to a first embodiment of the present disclosure will be described with reference to FIGS. 1 to 4. FIG. 1 shows a schematic perspective structure of the semiconductor light emitting device 10 according to the first embodiment. In FIG. 1, in order to facilitate understanding of the figure, an element container 40, which will be described later, is indicated by a two-dot chain line, and a diffusion layer 80 and a reflector 90, which will be described later, are omitted. FIG. 2 shows a schematic planar structure of the semiconductor light emitting device 10 of FIG. 1. In FIG. 2, the reflector 90 and the diffusion layer 80 are omitted in order to facilitate understanding of the figure. FIG. 3 shows a schematic cross-sectional structure of the semiconductor light emitting device 10 taken along line F3-F3 in FIG. 2. FIG. 4 shows a schematic planar structure in which the reflector 90 is added to FIG. 2. In FIG. 4, the diffusion layer 80 is omitted in order to facilitate understanding of the figure. Note that the term “plan view” used in the present disclosure refers to viewing the semiconductor light emitting device 10 or the constituent elements of the semiconductor light emitting device 10 in a Z direction of XYZ axes that are orthogonal to one another in FIG. 1.

As shown in FIG. 1, the semiconductor light emitting device 10 includes a surface

emitting laser element 20 serving as a light source, a light receiving element 30, and an element container 40 configured to contain the surface emitting laser element 20 and the light receiving element 30.

The element container 40 includes a bottom wall 50 where the surface emitting laser element 20 and the light receiving element 30 are arranged, and a peripheral wall 60 that surrounds both the surface emitting laser element 20 and the light receiving element 30 in a plan view. In an example, the bottom wall 50 and the peripheral wall 60 are integrally formed. The element container 40 is made of an insulating material. In an example, the element container 40 is made of a light shielding resin material. In the first embodiment, the element container 40 is made of a black epoxy resin.

As shown in FIGS. 1 and 2, the bottom wall 50 is formed in a rectangular flat plate shape with the Z direction being a thickness direction. In an example, the bottom wall 50 is formed in a rectangular shape with a longitudinal direction being the X direction and a lateral direction being a Y direction in a plan view. The bottom wall 50 includes a bottom wall front surface 51 and a bottom wall back surface 52 which face opposite sides from each other in the Z direction, and four bottom wall side surfaces 53 to 56 which connect the bottom wall front surface 51 and the bottom wall back surface 52. The bottom wall side surfaces 53 and 54 form both end surfaces of the bottom wall 50 in an X direction. The bottom wall side surfaces 55 and 56 form both end surfaces of the bottom wall 50 in the Y direction.

As shown in FIG. 3, the bottom wall 50 is provided with a plurality of terminals 70 which penetrate the bottom wall 50 in the Z direction. Each terminal 70 includes a terminal front surface 71 which faces the same side as the bottom wall front surface 51 (see FIG. 2) and a terminal back surface 72 which faces the same side as the bottom wall back surface 52. The terminal front surface 71 is exposed from the bottom wall front surface 51. The terminal back surface 72 is exposed from the bottom wall back surface 52. Each terminal 70 is made of a material containing, for example, copper (Cu), aluminum (Al), etc. In the first embodiment, each terminal 70 is made of a material containing Cu. Each terminal 70 is formed by etching a metal plate containing Cu.

As shown in FIG. 2, the plurality of terminals 70 include a first terminal 70A, a second terminal 70B, and a third terminal 70C. The first terminal 70A is a terminal where both the surface emitting laser element 20 and the light receiving element 30 are mounted. The second terminal 70B is a terminal electrically connected to the surface emitting laser element 20. The third terminal 70C is a terminal electrically connected to the light receiving element 30.

The first terminal 70A is formed over most of the bottom wall 50 in the X direction. The first terminal 70A is arranged to be close to the bottom wall side surface 56 in the Y direction. The second terminal 70B and the third terminal 70C are arranged to be closer to the bottom wall side surface 55 than the first terminal 70A in the Y direction. The second terminal 70B and the third terminal 70C are arranged at the same position in the Y direction and spaced apart from each other in the X direction. The second terminal 70B and the third terminal 70C are arranged at positions overlapping the first terminal 70A when viewed from the Y direction. The second terminal 70B is arranged to be closer to the bottom wall side surface 53 than the third terminal 70C.

The peripheral wall 60 is provided so as to rise in the Z direction from an outer periphery of the bottom wall 50. The peripheral wall 60 is formed in a rectangular frame shape in a plan view. The peripheral wall 60 may be divided into four side walls 61 to 64. The side walls 61 and 62 are provided at both ends of the bottom wall 50 in the X direction in a plan view. The side wall 61 is provided at an end, which is closer to the bottom wall side surface 53, of both ends of the bottom wall 50 in the X direction in a plan view. The side wall 62 is provided at an end, which is closer to the bottom wall side surface 54, of both ends of the bottom wall 50 in the X direction in a plan view. The side walls 63 and 64 are provided at both ends of the bottom wall 50 in the Y direction in a plan view. The side wall 63 is provided at an end, which is closer to the bottom wall side surface 55, of both ends of the bottom wall 50 in the Y direction in a plan view. The side wall 64 is provided at an end, which is closer to the bottom wall side surface 56, of both ends of the bottom wall 50 in the Y direction in a plan view.

The peripheral wall 60 includes a peripheral wall front surface 65 facing the same side as the bottom wall front surface 51, a peripheral wall inner side surface 66, and a peripheral wall outer side surface 67. In an example, the peripheral wall outer side surface 67 is formed so as to be flush with the bottom wall side surfaces 53 to 56 of the bottom wall 50. The peripheral wall inner side surface 66 is a side surface of the peripheral wall 60 on an opposite side of the peripheral wall outer side surface 67.

In an example, as shown in FIGS. 2 and 3, the peripheral wall inner side surface 66 is constituted by an inclined surface that inclines outward from the element container 40 as the peripheral wall inner side surface 66 extends from the bottom wall front surface 51 to the peripheral wall front surface 65. In an example, the peripheral wall inner side surface 66 of the side wall 61 is constituted by an inclined surface that inclines toward the bottom wall side surface 53 as the peripheral wall inner side surface 66 extends from the bottom wall front surface 51 to the peripheral wall front surface 65. The peripheral wall inner side surface 66 of the side wall 62 is constituted by an inclined surface that inclines toward the bottom wall side surface 54 as the peripheral wall inner side surface 66 extends from the bottom wall front surface 51 to the peripheral wall front surface 65. The peripheral wall inner side surface 66 of the side wall 63 is constituted by an inclined surface that inclines toward the bottom wall side surface 55 as the peripheral wall inner side surface 66 extends from the bottom wall front surface 51 to the peripheral wall front surface 65. The peripheral wall inner side surface 66 of the side wall 64 is constituted by an inclined surface that inclines toward the bottom wall side surface 56 as the peripheral wall inner side surface 66 extends from the bottom wall front surface 51 to the peripheral wall front surface 65. The peripheral wall inner side surface 66 may be a flat surface extending in the Z direction.

In an example shown in FIG. 3, the peripheral wall outer side surface 67 is constituted by a plane extending in the Z direction. As shown in FIG. 2, in an example, the peripheral wall outer side surface 67 of the side wall 61 is constituted by an XZ plane and is formed to be flush with the bottom wall side surface 53. The peripheral wall outer side surface 67 of the side wall 62 is constituted by an XZ plane and is formed to be flush with the bottom wall side surface 54. The peripheral wall outer side surface 67 of the side wall 63 is constituted by a YZ plane and is formed to be flush with the bottom wall side surface 55. The peripheral wall outer side surface 67 of the side wall 64 is constituted by a YZ plane and is formed to be flush with the bottom wall side surface 56.

As shown in FIG. 3, the element container 40 forms a containing space 41 by the bottom wall 50 and the peripheral wall 60. The containing space 41 is a space that contains the surface emitting laser element 20 and the light receiving element 30. The element container 40 is open on the same side as the peripheral wall front surface 65. In an example, the containing space 41 is formed so that a planar area perpendicular to the Z direction increases as the containing space 41 extends away from the bottom wall front surface 51 in the Z direction.

The surface emitting laser element 20 contained in the containing space 41 of the element container 40 is formed in a rectangular flat plate shape with the thickness direction being the Z direction. Therefore, the Z direction may be said to be a “thickness direction of the surface emitting laser element 20.” The surface emitting laser element 20 may be a VCSEL element or a two-dimensional photonic crystal surface emitting laser element. In an example, the surface emitting laser element 20 is a VCSEL element.

The surface emitting laser element 20 includes an element front surface 21 and an element back surface 22 facing opposite sides from each other in the Z direction, and four element side surfaces 23 which connect the element front surface 21 and the element back surface 22. The element front surface 21 faces the same side as the peripheral wall front surface 65 of the peripheral wall 60 of the element container 40. Therefore, it may be said that the element container 40 is open on the same side as the element front surface 21. Herein, the Z direction is a direction perpendicular to the element front surface 21. Therefore, a plan view means “viewing from a direction perpendicular to the element front surface 21.”

The surface emitting laser element 20 is configured to emit laser light from the element front surface 21. The laser light is emitted from the element front surface 21 in the Z direction. In an example, as shown in FIG. 2, the surface emitting laser element 20 includes a plurality of light emitting parts 24 formed at the element front surface 21. Each of the plurality of light emitting parts 24 is configured to emit laser light from the element front surface 21 in the Z direction. It may be said that the surface emitting laser element 20 includes a light emitting region 25 where the plurality of light emitting parts 24 are formed. The light emitting region 25 may be defined as a broken-line region that surrounds all the light emitting parts 24 in the element front surface 21. A shape of the light emitting region 25 in a plan view is changed according to an arrangement of the plurality of light emitting parts 24. In the example shown in FIG. 2, the shape of the light emitting region 25 in a plan view is rectangular.

As shown in FIG. 3, the surface emitting laser element 20 includes an element substrate 26. The element substrate 26 may include a semiconductor substrate containing, for example, gallium arsenide (GaAs), and a semiconductor layer over the semiconductor substrate. The semiconductor layer may include a plurality of semiconductor layers, such as an active layer and a distributed Bragg reflector (DBR) layer, and a conductive layer. The plurality of light emitting parts 24 are provided at the element substrate 26.

As shown in FIG. 2, a front surface electrode 27 is formed at the element front surface 21. The surface emitting laser element 20 includes a conductive layer that is provided on the element substrate 26 and is electrically connected to the plurality of light emitting parts 24. The front surface electrode 27 is electrically connected to the conductive layer. The front surface electrode 27 is formed in a strip shape extending in the Y direction in a plan view. In an example, the front surface electrode 27 is provided at an end, which is on an opposite side of the element front surface 21 from the light receiving element 30, of both ends of the element front surface 21 in the X direction. In other words, the front surface electrode 27 is provided at an end, which is closer to the side wall 61, of both ends of the element front surface 21 in the X direction.

As shown in FIG. 2, the front surface electrode 27 is electrically connected to the second terminal 70B by a first wire W1. In this manner, the front surface electrode 27 is constituted as a region where the first wire WI is connected. In the example shown in FIG. 2, the first wire W1 extends along the Y direction in a plan view. The first wire W1 is, for example, a bonding wire. The first wire W1 contains at least one selected from the group of Au (gold), Al, and Cu.

As shown in FIG. 3, a back surface electrode 28 is formed at the element back surface 22. In an example, the back surface electrode 28 is formed at the entire surface of the element back surface 22. In an example, the back surface electrode 28 constitutes a cathode electrode. In an example, the front surface electrode 27 constitutes an anode electrode.

The surface emitting laser element 20 is mounted on the first terminal 70A. More specifically, the surface emitting laser element 20 is bonded to the terminal front surface 71 of the first terminal 70A by a conductive bonding material SD. As a result, the back surface electrode 28 of the surface emitting laser element 20 is electrically connected to the first terminal 70A via the conductive bonding material SD.

The light receiving element 30 contained in the containing space 41 of the element container 40 is formed in a rectangular flat plate shape with the thickness direction being the Z direction. The light receiving element 30 is arranged to be spaced apart from the surface emitting laser element 20 in the X direction. In the example shown in FIG. 2, the light receiving element 30 is arranged to be closer to the side wall 62 than the surface emitting laser element 20.

As shown in FIGS. 2 and 3, the light receiving element 30 includes a light receiving front surface 31 and a light receiving back surface 32 which face opposite sides from each other in the Z direction, and a light receiving side surface 33 connecting the light receiving front surface 31 and the light receiving back surface 32. The light receiving element 30 is, for example, a photodiode.

The light receiving front surface 31 faces the same side as the element front surface 21 of the surface emitting laser element 20. A light receiving region 34 and a front surface electrode 35 are formed at the light receiving front surface 31. The front surface electrode 35 is, for example, provided at a position overlapping the light receiving region 34 in a plan view.

As shown in FIG. 2, the front surface electrode 35 is electrically connected to the third terminal 70C by a second wire W2. In the example shown in FIG. 2, the second wire W2 extends along the Y direction in a plan view. The second wire W2 is, for example, a bonding wire. The second wire W2 contains at least one selected from the group of Au, Al, and Cu. The second wire W2 may be made of, for example, the same material as the first wire W1.

As shown in FIG. 3, the light receiving back surface 32 faces the same side as the element back surface 22 of the surface emitting laser element 20. A back surface electrode 36 is formed at the light receiving back surface 32. In an example, the back surface electrode 36 is formed at the entire light receiving back surface 32. In an example, the back surface electrode 36 constitutes a cathode electrode. In an example, the front surface electrode 35 constitutes an anode electrode.

The light receiving element 30 is mounted on the first terminal 70A. More specifically, the light receiving element 30 is bonded to the terminal front surface 71 of the first terminal 70A by a conductive bonding material SD. As a result, the back surface electrode 36 of the light receiving element 30 is electrically connected to the first terminal 70A via the conductive bonding material SD. Therefore, it may be said that the back surface electrode 36 of the light receiving element 30 is electrically connected to the back surface electrode 28 of the surface emitting laser element 20. In addition, since the surface emitting laser element 20 and the light receiving element 30 are mounted on the terminal front surface 71 of the common first terminal 70A, it may be said that the surface emitting laser element 20 and the light receiving element 30 are arranged over the same plane.

Herein, in the example shown in FIG. 3, a thickness of the surface emitting laser element 20 and a thickness of the light receiving element 30 are equal to each other. Therefore, the element front surface 21 of the surface emitting laser element 20 and the light receiving front surface 31 of the light receiving element 30 are at the same position in the Z direction. More specifically, a distance DI between the terminal front surface 71 of the first terminal 70A and the element front surface 21 of the surface emitting laser element 20 in the Z direction is equal to a distance D2 between the terminal front surface 71 of the first terminal 70A and the light receiving front surface 31 of the light receiving element 30 in the Z direction. The thickness of the surface emitting laser element 20 may be defined by a distance between the element front surface 21 and the element back surface 22 of the surface emitting laser element 20 in the Z direction. The thickness of the light receiving element 30 may be defined by a distance between the light receiving front surface 31 and the light receiving back surface 32 of the light receiving element 30 in the Z direction.

As shown in FIG. 3, the semiconductor light emitting device 10 includes the diffusion layer 80 and the reflector 90. The reflector 90 covers at least one selected from the group of the bottom wall 50 and the peripheral wall 60 in the containing space 41 of the element container 40. In the example shown in FIG. 3, the reflector 90 covers both the bottom wall 50 and the peripheral wall 60. The reflector 90 is made of a resin material having a higher light reflectivity than the diffusion layer 80. In an example, the reflector 90 is made of a white resin material. For example, an epoxy resin mixed with titanium oxide or silica may be used as the white resin material.

As shown in FIG. 4, the reflector 90 covers the entire bottom wall 50 in a plan view. Therefore, the terminal front surfaces 71 of the first to third terminals 70A to 70C are covered by the reflector 90. In addition, the reflector 90 is in contact with both the conductive bonding material SD between the surface emitting laser element 20 and the first terminal 70A and the conductive bonding material SD between the light receiving element 30 and the first terminal 70A. In FIG. 4, the reflector 90 is indicated by dots.

As shown in FIGS. 3 and 4, the reflector 90 covers the four element side surfaces 23 of the surface emitting laser element 20. The reflector 90 also covers four light receiving side surfaces 33 of the light receiving element 30. Therefore, as shown in FIG. 4, the reflector 90 contacts a portion of the first wire W1 that is closer to the bottom wall front surface 51 than the element front surface 21 of the surface emitting laser element 20. The reflector 90 contacts a portion of the second wire W2 that is closer to the bottom wall front surface 51 than the light receiving front surface 31 of the light receiving element 30.

As shown in FIGS. 3 and 4, the reflector 90 covers the entire peripheral wall inner side surface 66 of the peripheral wall 60. More specifically, the reflector 90 covers the entire peripheral wall inner side surface 66 of each of the side walls 61 to 64. The reflector 90 contacts the entire peripheral wall inner side surface 66 of each of the side walls 61 to 64.

The reflector 90 includes a front surface 91. As shown in FIG. 3, the front surface 91 includes a curved concave shape formed so as to extend toward the peripheral wall front surface 65 as the front surface 91 extends from the surface emitting laser element 20 to the side wall 61 of the peripheral wall 60. Although not shown in FIG. 3, the front surface 91 includes a curved concave shape formed so as to extend toward the peripheral wall front surface 65 as the front surface 91 extends from the surface emitting laser element 20 to the side wall 63 (see FIG. 4) of the peripheral wall 60. The front surface 91 includes a curved concave shape formed so as to extend toward the peripheral wall front surface 65 as the front surface 91 extends from the surface emitting laser element 20 to the side wall 64 (see FIG. 4) of the peripheral wall 60. The front surface 91 of the portion of the reflector 90, which is filled between the surface emitting laser element 20 and the light receiving element 30 in the X direction, includes a curved concave shape formed so as to be recessed toward the terminal front surface 71 of the first terminal 70A as the front surface 91 extends toward a center between the surface emitting laser element 20 and the light receiving element 30 in the X direction.

The front surface 91 includes a curved concave shape formed so as to extend toward the peripheral wall front surface 65 as the front surface 91 extends from the light receiving element 30 to the side wall 62 of the peripheral wall 60. Although not shown in FIG. 3, the front surface 91 includes a curved concave shape formed so as to extend toward the peripheral wall front surface 65 as the front surface 91 extends from the light receiving element 30 to the side wall 63 of the peripheral wall 60. The front surface 91 includes a curved concave shape formed so as to extend toward the peripheral wall front surface 65 as the front surface 91 extends from the light receiving element 30 to the side wall 64 of the peripheral wall 60. The front surface 91 of the reflector 90 is inclined so as to approach the peripheral wall inner side surface 66 as the front surface 91 approaches the peripheral wall front surface 65. In an example, an outer peripheral edge of the front surface 91 is connected to an inner peripheral edge of the peripheral wall front surface 65.

The diffusion layer 80 covers both the element front surface 21 of the surface emitting laser element 20 and the light receiving front surface 31 of the light receiving element 30 in the containing space 41 of the element container 40. In an example, the diffusion layer 80 contacts both the element front surface 21 and the light receiving front surface 31. It may be said that the diffusion layer 80 covers both the element front surface 21 and the light receiving front surface 31. The diffusion layer 80 is provided over the reflector 90. In an example, the diffusion layer 80 contacts the front surface 91 of the reflector 90.

The diffusion layer 80 includes a translucent resin layer 81 and a plurality of diffusion materials 82 formed in the resin layer 81. The resin layer 81 is made of, for example, a transparent resin material. The resin layer 81 contacts the entire front surface 91 of the reflector 90. Therefore, an area of the diffusion layer 80 in a planar direction perpendicular to the Z direction is gradually increased from the element front surface 21 of the surface emitting laser element 20 toward the peripheral wall front surface 65 in the Z direction. The resin layer 81 includes a front surface 83. In an example, the front surface 83 is formed so as to be at the same position as the peripheral wall front surface 65 of the peripheral wall 60 in the Z direction.

The plurality of diffusion materials 82 are distributed, as fine particles that diffuse light, in the resin layer 81. The diffusion materials 82 diffuse the light inside the resin layer 81 by reflecting (scattering) the light at interfaces between the resin in the resin layer 81 and the diffusion materials 82. As a result, the light receiving element 30 receives a portion of laser light that is emitted from the element front surface 21 of the surface emitting laser element 20 and diffused by the diffusion materials 82 in the diffusion layer 80. In addition, the diffusion materials 82 serve to widen a directional angle of the laser light emitted from the diffusion layer 80 by diffusing the laser light emitted from the element front surface 21 of the surface emitting laser element 20 within the diffusion layer 80.

Material of the diffusion materials 82 is not particularly limited, but for example, silica or other glass materials may be used. In an example, a spherical silica filler is used as the diffusion materials 82. A particle size of the diffusion material 82 is not particularly limited, but for example, a particle size that is sufficiently small relative to a wavelength of the laser light emitted from the surface emitting laser element 20 is selected such that scattering occurs predominantly.

The diffusion materials 82 are mixed with the resin layer 81 at a predetermined

compounding ratio. In an example, the diffusion materials 82 are evenly distributed within the resin layer 81. The compounding ratio of the diffusion materials 82 to the resin layer 81 is not particularly limited, and may be greater than 0% and less than 100%. As the compounding ratio of the diffusion materials 82 is increased, the light receiving element 30 may receive scattered light more easily, thereby widening the directional angle of the laser light of the surface emitting laser element 20. In addition, by limiting an upper limit of the compounding ratio of the diffusion materials 82 to a predetermined value, it is possible to suppress a large decrease in an output and a radiation intensity of the laser light of the semiconductor light emitting device 10.

In an example, a material having a smaller linear expansion coefficient than the resin layer 81 is selected as the diffusion materials 82. In such a configuration, a thermal stress generated in the diffusion layer 80 by the diffusion materials 82 can be reduced as compared to a case where the diffusion layer 80 is composed of only the resin layer 81. This makes it possible to suppress disconnection of the first wire W1 and the second wire W2 due to the thermal stress of the diffusion layer 80.

The light receiving element 30 receives a portion of the laser light emitted from the surface emitting laser element 20. Therefore, the semiconductor light emitting device 10 can monitor a state of the surface emitting laser element 20 by using the light receiving element 30. The semiconductor light emitting device 10 can use so-called an auto power control (APC) drive to control a current supplied to the surface emitting laser element 20 such that a light output of the laser light of the surface emitting laser element 20 is constant. More specifically, a controller which is provided outside the semiconductor light emitting device 10 and configured to control the current supplied to the surface emitting laser element 20 receives a signal corresponding to a reflected light, which is obtained by an action of the diffusion layer 80, of the laser light of the surface emitting laser element 20 received by the light receiving element 30. The controller receives the signal of the light receiving element 30 by being electrically connected to the third terminal 70C. Then, the controller controls the current supplied to the surface emitting laser element 20 according to a difference between the received signal and an output setting value that becomes a preset light output. In an example, the controller controls the current supplied to the surface emitting laser element 20 so that a level of the received signal matches the output setting value.

### Operation of First Embodiment

An operation of the semiconductor light emitting device 10 according to the first embodiment will be described. In the semiconductor light emitting device 10, the laser light emitted from the surface emitting laser element 20 is diffused in the diffusion layer 80. As a result, the laser light emitted from the semiconductor light emitting device 10 has a wide directional angle. In this manner, the semiconductor light emitting device 10 can achieve both a high output and a wide directional angle of the emitted light.

The diffused laser light is directed toward, for example, the bottom wall 50 and the peripheral wall 60 of the element container 40. At the bottom wall 50 and the peripheral wall 60, absorption of the laser light occurs. On the other hand, the reflector 90 reflects the laser light directed toward the bottom wall 50 and the peripheral wall 60. The reflected laser light passes through an opening of the element container 40 and is emitted to an outside of the semiconductor light emitting device 10. In this manner, the laser light of the surface emitting laser element 20 is diffused by the diffusion layer 80. Further, the diffused laser light is reflected by the reflector 90 and emitted to the outside without being absorbed by the bottom wall 50 and the peripheral wall 60 of the element container 40. This allows the semiconductor light emitting device 10 to suppress absorption of the laser light at the bottom wall 50 and the peripheral wall 60, thereby improving the light output.

### Effects of First Embodiment

The semiconductor light emitting device 10 according to the first embodiment provides the following effects.

(1-1) The semiconductor light emitting device 10 includes the surface emitting laser element 20 including the element front surface 21 and configured to emit the laser light from the element front surface 21; the element container 40 including the bottom wall 50 where the surface emitting laser element 20 is arranged, and the peripheral wall 60 surrounding the surface emitting laser element 20 in a plan view, the bottom wall 50 and the peripheral wall 60 constituting the containing space 41 which contains the surface emitting laser element 20 and is open on the same side as the element front surface 21; the diffusion layer 80 which covers the element front surface 21 in the containing space 41 and includes the diffusion materials 82; and the reflector 90 which covers at least one selected from the group of the bottom wall 50 and the peripheral wall 60 in the containing space 41 and is made of a resin material having a higher light reflectivity than the diffusion layer 80. The reflector 90 is configured to reflect the laser light emitted from the element front surface 21 and diffused by the diffusion materials 82.

According to the above-described configuration, since the laser light emitted from the surface emitting laser element 20 is diffused by the diffusion layer 80, it is possible to achieve both a high output and a wide directional angle of the laser light. In addition, since the diffused laser light is reflected by the reflector 90 configured to cover at least one selected from the group of the bottom wall 50 and the peripheral wall 60, it is possible to improve a light output of the semiconductor light emitting device 10.

(1-2) The reflector 90 covers both the bottom wall 50 and the peripheral wall 60 of the element container 40. According to this configuration, the laser light diffused by the diffusion layer 80 can be prevented by the reflector 90 configured to cover both the bottom wall 50 and the peripheral wall 60 from being absorbed by both the bottom wall 50 and the peripheral wall 60. Therefore, it is possible to further improve the light output of the semiconductor light emitting device 10.

(1-3) The peripheral wall 60 includes the peripheral wall front surface 65 which faces the same side as the element front surface 21 of the surface emitting laser element 20 and is provided at a position farther from the bottom wall 50 than the element front surface 21. The reflector 90 covers the peripheral wall 60. The front surface 91 of the reflector 90 includes a curved concave shape formed so as to extend toward the peripheral wall front surface 65 as the front surface 91 extends from the surface emitting laser element 20 to the peripheral wall 60.

According to the above-described configuration, a reflection direction can be distributed when the diffused laser light is reflected by the curved concave front surface 91 of the reflector 90, as compared to when the front surface 91 of the reflector 90 is a flat surface. Therefore, it is possible to further widen the directional angle of the semiconductor light emitting device 10.

(1-4) The surface emitting laser element 20 includes the element back surface 22 facing an opposite side from the element front surface 21, and the element side surface 23 connecting the element front surface 21 and the element back surface 22. The reflector 90 covers the element side surface 23.

According to the above-described configuration, the laser light diffused by the diffusion layer 80 may be directed toward the element side surface 23 of the surface emitting laser element 20. Since the element side surface 23 is covered by the reflector 90, the laser light directed toward the element side surface 23 is reflected by the reflector 90. This prevents the laser light from being absorbed by the element side surface 23, thereby improving the light output of the semiconductor light emitting device 10.

(1-5) The surface emitting laser element 20 includes the light emitting region 25 formed at the element front surface 21. The diffusion layer 80 entirely covers the light emitting region 25 in a plan view. According to this configuration, all of the laser light emitted from the surface emitting laser element 20 is incident on the diffusion layer 80. Therefore, all of the laser light emitted from the surface emitting laser element 20 is diffused by the diffusion layer 80. Therefore, the semiconductor light emitting device 10 can emit the laser light with a wide directional angle.

(1-6) The reflector 90 is made of a white resin material. This configuration makes it easier for the reflector 90 to reflect the diffused laser light. Therefore, it is possible to improve the light output of the semiconductor light emitting device 10.

(1-7) The semiconductor light emitting device 10 includes the light receiving element 30 arranged at the bottom wall 50 in the containing space 41. The light receiving element 30 is configured to receive the laser light emitted from the element front surface 21 of the surface emitting laser element 20 and diffused by the diffusion materials 82.

With the above-described configuration, it is possible to grasp the light output of the laser light emitted by the surface emitting laser element 20 when the light receiving element 30 receives the diffused laser light. This makes it easier to control the light output of the surface emitting laser element 20.

(1-8) The light receiving element 30 includes the light receiving front surface 31 which faces the same side as the element front surface 21 of the surface emitting laser element 20 and includes the light receiving region 34 where the laser light is received, the light receiving back surface 32 which faces an opposite side from the light receiving front surface 31, and the light receiving side surface 33 connecting the light receiving front surface 31 and the light receiving back surface 32. The reflector 90 covers the light receiving side surface 33.

According to the above-described configuration, the laser light diffused by the diffusion layer 80 may be directed toward the light receiving side surface 33 of the light receiving element 30. Since the light receiving side surface 33 is covered by the reflector 90, the laser light directed toward the light receiving side surface 33 is reflected by the reflector 90. This prevents the laser light from being absorbed by the light receiving side surface 33, thereby improving the light output of the semiconductor light emitting device 10.

(1-9) The element front surface 21 of the surface emitting laser element 20 and the light receiving front surface 31 of the light receiving element 30 are at the same position in the Z direction. According to this configuration, it is possible to prevent the reflector 90 from covering either the element front surface 21 of the surface emitting laser element 20 or the light receiving front surface 31 of the light receiving element 30. Therefore, it is possible to improve the light output of the laser light when the element front surface 21 of the surface emitting laser element 20 is covered with the reflector 90 or to prevent a decrease in detection accuracy when the light receiving front surface 31 of the light receiving element 30 is covered with the reflector 90.

(1-10) The reflector 90 is provided between the surface emitting laser element 20 and the light receiving element 30. The front surface 91 of the reflector 90 provided between the surface emitting laser element 20 and the light receiving element 30 includes a curved concave shape.

According to the above-described configuration, the reflection direction can be distributed in a case where the diffused laser light is reflected by the curved concave front surface 91 of the reflector 90, as compared to a case where the front surface 91 of the reflector 90 is a flat surface. Therefore, it is possible to further widen the directional angle of the semiconductor light emitting device 10.

(1-11) The light emitting region 25 and the front surface electrode 27 are formed to be spaced apart from each other in the X direction on the element front surface 21 of the surface emitting laser element 20. The light receiving element 30 is arranged on an opposite side of the light emitting region 25 from the front surface electrode 27 in the X direction.

According to the above-described configuration, a distance between the light emitting region 25 of the surface emitting laser element 20 and the light receiving element 30 in the X direction can be shortened. Therefore, the light receiving element 30 can easily receive the laser light emitted from the element front surface 21 of the surface emitting laser element 20.

### Second Embodiment

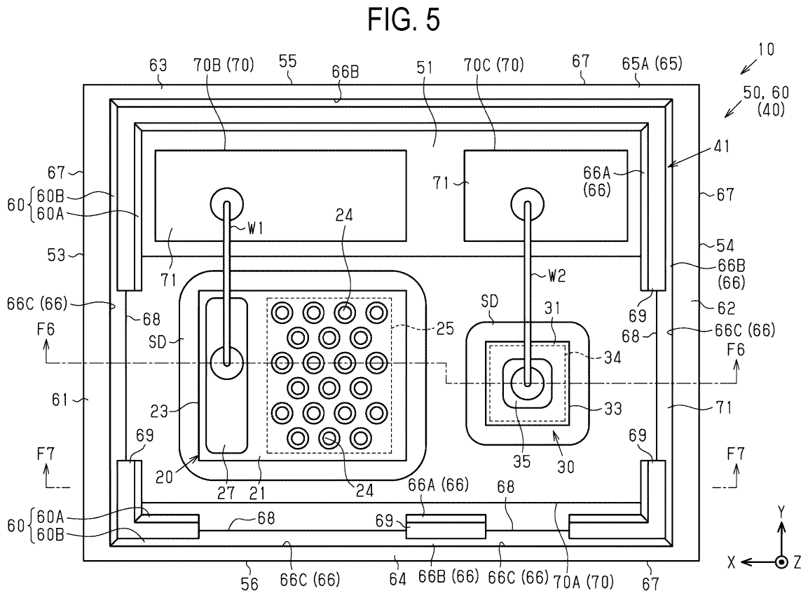

A semiconductor light emitting device 10 according to a second embodiment of the present disclosure will be described with reference to FIGS. 5 to 7. The semiconductor light emitting device 10 according to the second embodiment is mainly different from the semiconductor light emitting device 10 according to the first embodiment in terms of the configuration of the peripheral wall 60 of the element container 40. Hereinafter, features different from the first embodiment will be described. Meanwhile, the same constituent elements as in the first embodiment are denoted by the same reference numerals, and explanation thereof will be omitted.

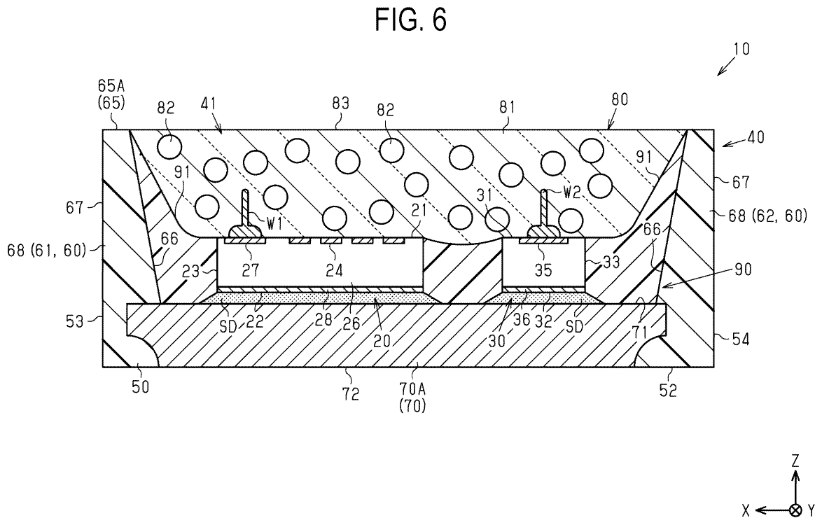

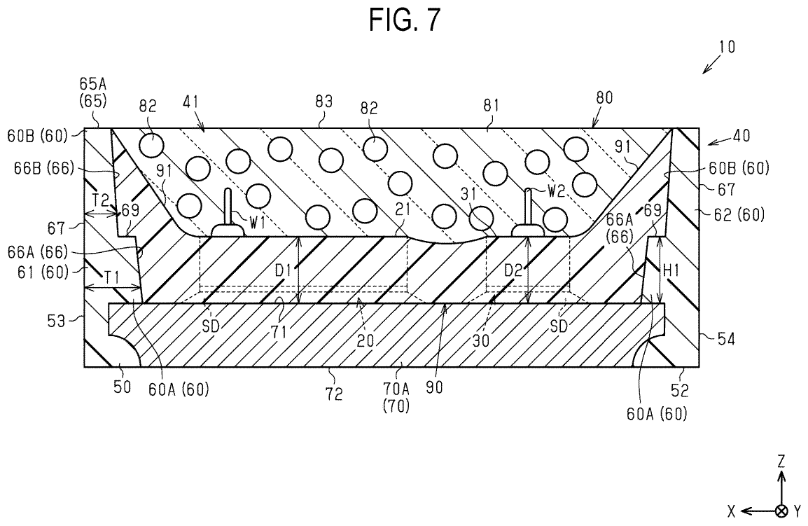

FIG. 5 shows a schematic planar structure of the semiconductor light emitting device 10 according to the second embodiment. In FIG. 5, both the diffusion layer 80 and the reflector 90 are omitted in order to facilitate understanding of the figure. FIG. 6 shows a schematic cross-sectional structure of the semiconductor light emitting device 10 taken along line F6-F6 in FIG. 5. FIG. 7 shows a schematic cross-sectional structure of the semiconductor light emitting device 10 taken along line F7-F7 in FIG. 5.

As shown in FIG. 5, the peripheral wall 60 includes a thin wall 68 having a small thickness. A plurality of thin walls 68 are provided to be spaced apart from each other in a direction in which the peripheral wall 60 extends in a plan view. In the example shown in FIG. 5, the thin walls 68 are provided at the side wall 61 of the peripheral wall 60 close to the surface emitting laser element 20 in the X direction, the side wall 62 of the peripheral wall 60 close to the light receiving element 30 in the X direction, and the side wall 64 of the peripheral wall 60 close to both the surface emitting laser element 20 and the light receiving element 30 in the Y direction.

The thin wall 68 includes a peripheral wall inner side surface 66C. In a plan view, the peripheral wall inner side surface 66C is located at an outer side of the bottom wall front surface 51 than a peripheral wall inner side surface 66 of a portion of the peripheral wall 60 other than the thin wall 68. In other words, since the peripheral wall inner side surface 66C is located at the outer side of the bottom wall front surface 51, the thin wall 68 is thinner than the portion of the peripheral wall 60 other than the thin wall 68.

The thin wall 68 of the side wall 61 is arranged at a position overlapping the surface emitting laser element 20 when viewed from the X direction. In an example, when viewed in a plan view, a dimension of the thin wall 68 in the Y direction is equal to or larger than a dimension of the surface emitting laser element 20 in the Y direction. In the example shown in FIG. 5, when viewed in a plan view, the dimension of the thin wall 68 in the Y direction is equal to the dimension of the surface emitting laser element 20 in the Y direction.

The thin wall 68 of the side wall 62 is arranged at a position overlapping the light receiving element 30 when viewed from the X direction. In an example, when viewed in a plan view, the dimension of the thin wall 68 in the Y direction is equal to or larger than the dimension of the light receiving element 30 in the Y direction. In the example shown in FIG. 5, when viewed in a plan view, the dimension of the thin wall 68 in the Y direction is larger than the dimension of the light receiving element 30 in the Y direction.

As shown in FIGS. 5 and 6, a distance in the X direction between the surface emitting laser element 20 and the side wall 61 in the thin wall 68 of the side wall 61 is larger than a distance in the X direction between the surface emitting laser element 20 and the side wall 61 in a portion of the side wall 61 other than the thin wall 68.

A distance in the X direction between the light receiving element 30 and the side wall 62 in the thin wall 68 of the side wall 62 is larger than a distance in the X direction between the light receiving element 30 and the side wall 62 in a portion of the side wall 62 other than the thin wall 68.

As shown in FIG. 6, the peripheral wall inner side surface 66C of the thin wall 68 in the side wall 61 is constituted by an inclined surface that is inclined toward the bottom wall side surface 53 as it extends from the bottom wall front surface 51 of the bottom wall 50 toward the peripheral wall front surface 65 of the peripheral wall 60. The peripheral wall inner side surface 66C of the thin wall 68 in the side wall 62 is constituted by an inclined surface that is inclined toward the bottom wall side surface 54 as it extends from the bottom wall front surface 51 of the bottom wall 50 toward the peripheral wall front surface 65 of the peripheral wall 60.

As shown in FIG. 7, in the second embodiment, the portion of the peripheral wall 60 other than the thin wall 68 includes a first peripheral wall 60A close to the bottom wall 50 in the Z direction, and a second peripheral wall 60B on the opposite side of the first peripheral wall 60A from the bottom wall 50. The first peripheral wall 60A and the second peripheral wall 60B are integrally formed.

A thickness T1 of the first peripheral wall 60A is larger than a thickness T2 of the second peripheral wall 60B. In other words, the thickness T2 of the second peripheral wall 60B is smaller than the thickness T1 of the first peripheral wall 60A. Herein, the thickness T1 of the first peripheral wall 60A is a dimension in a direction perpendicular to both a direction in which the first peripheral wall 60A extends and the Z direction in a plan view. The thickness T2 of the second peripheral wall 60B is a dimension in a direction perpendicular to both a direction in which the second peripheral wall 60B extends and the Z direction in a plan view.

The thickness T1 of the first peripheral wall 60A becomes thinner as it extends away from the bottom wall 50 in the Z direction. The thickness T2 of the second peripheral wall 60B becomes thinner as it extends away from the bottom wall 50 in the Z direction. In an example, a minimum value of the thickness T1 of the first peripheral wall 60A is larger than a maximum value of the thickness T2 of the second peripheral wall 60B. Therefore, a step 69 is formed by the first peripheral wall 60A and the second peripheral wall 60B.

The first peripheral wall 60A includes a peripheral wall inner side surface 66A. The second peripheral wall 60B includes a peripheral wall inner side surface 66B. In a plan view, the peripheral wall inner side surface 66B is located at an outer side of the bottom wall front surface 51 than the peripheral wall inner side surface 66A. The peripheral wall inner side surface 66B is spaced apart from the peripheral wall inner side surface 66A in a plan view. Therefore, in a plan view, a step 69 is formed between the peripheral wall inner side surface 66A and the peripheral wall inner side surface 66B. Herein, the peripheral wall inner side surface 66B is an example of an “inner side surface constituting the second peripheral wall 60B.”

In the Z direction, the step 69 of the side wall 61 is formed at the same position as the element front surface 21 of the surface emitting laser element 20. In other words, a height H1 of the first peripheral wall 60A is equal to a distance DI between the terminal front surface 71 of the first terminal 70A and the element front surface 21 of the surface emitting laser element 20 in the Z direction. Herein, the height Hl of the first peripheral wall 60A may be defined by a distance between the terminal front surface 71 of the first terminal 70A and a first peripheral wall front surface 65A of the first peripheral wall 60A in the Z direction. The first peripheral wall front surface 65A is a surface constituting the step 69 and faces the same side as the peripheral wall front surface 65.

In the Z direction, the step 69 of the side wall 62 is formed at the same position as the light receiving front surface 31 of the light receiving element 30. In other words, the height H1 of the first peripheral wall 60A is equal to a distance D2 between the terminal front surface 71 of the first terminal 70A and the light receiving front surface 31 of the light receiving element 30 in the Z direction.

The reflector 90 covers the peripheral wall inner side surface 66A of the first peripheral wall 60A. The reflector 90 covers the step 69. The reflector 90 covers the peripheral wall inner side surface 66B of the second peripheral wall 60B. As shown in FIG. 6, the reflector 90 entirely covers the peripheral wall inner side surface 66C of the thin wall 68. The diffusion layer 80 is formed over the reflector 90 in the same manner as in the first embodiment.

### Effects of Second Embodiment

The semiconductor light emitting device 10 according to the second embodiment provides the following effects.

(2-1) The surface emitting laser element 20 is arranged so as to be close to a portion of the peripheral wall 60 of the element container 40. The portion of the peripheral wall 60 close to the surface emitting laser element 20 includes a portion having a thickness that is smaller than a thickness of a portion of the peripheral wall 60 farther from the surface emitting laser element 20 than the portion of the peripheral wall 60 close to the surface emitting laser element 20.

According to the above-described configuration, when the surface emitting laser element 20 is asymmetrically arranged with respect to the peripheral wall 60 in a plan view, it is possible to increase a distance between the surface emitting laser element 20 and the peripheral wall 60 by reducing the thickness of the peripheral wall 60 close to the surface emitting laser element 20. As a result, it is possible to prevent the reflector 90 provided between the surface emitting laser element 20 and the peripheral wall 60 from climbing up onto the element front surface 21 to cover the element front surface 21 of the surface emitting laser element 20.

(2-2) The peripheral wall 60 includes the first peripheral wall 60A close to the bottom wall 50 in the Z direction, the second peripheral wall 60B located on an opposite side of the first peripheral wall 60A from the bottom wall 50 in the Z direction and having a thickness smaller than a thickness of the first peripheral wall 60A, and the step 69 formed by the first peripheral wall 60A and the second peripheral wall 60B. In the Z direction, the step 69 is located at the same position as the element front surface 21 or located to be closer to the bottom wall 50 than the element front surface 21.

According to the above-described configuration, when the step 69 and the element front surface 21 of the surface emitting laser element 20 are at the same position in the Z direction, the reflector 90 is provided over the step 69, such that it is possible to prevent the reflector 90 from covering the element front surface 21. Further, when the step 69 is located to be closer to the bottom wall 50 than the element front surface 21, the reflector 90 covers the step 69 before covering the element front surface 21. As a result, it is possible to prevent the reflector 90 from being formed to cover the element front surface 21 of the surface emitting laser element 20.

(2-3) The reflector 90 covers the step 69. According to this configuration, by covering the step 69 with the reflector 90, the diffused laser light can be prevented from being absorbed by the step 69. As a result, it is possible to improve the light output of the semiconductor light emitting device 10.

(2-4) The reflector 90 covers the peripheral wall inner side surface 66B of the second peripheral wall 60B. According to this configuration, by covering the peripheral wall inner side surface 66B of the second peripheral wall 60B with the reflector 90, the diffused laser light can be prevented from being absorbed by the peripheral wall inner side surface 66B. As a result, it is possible to improve the light output of the semiconductor light emitting device 10.

(2-5) The light receiving element 30 is arranged so as to be close to a portion of the peripheral wall 60. The portion of the peripheral wall 60 close to the light receiving element 30 includes a portion having a thickness that is smaller than a thickness of a portion of the peripheral wall 60 which is farther from the light receiving element 30 than the portion of the peripheral wall 60 close to the light receiving element 30.

According to the above-described configuration, when the light receiving element 30 is asymmetrically arranged with respect to the peripheral wall 60 in a plan view, it is possible to increase a distance between the light receiving element 30 and the peripheral wall 60 by reducing the thickness of the peripheral wall 60 close to the light receiving element 30. As a result, it is possible to prevent the reflector 90 provided between the light receiving element 30 and the peripheral wall 60 from climbing up onto the light receiving front surface 31 to cover the light receiving front surface 31 of the light receiving element 30.

(2-6) The portion of the peripheral wall 60 close to the surface emitting laser element 20 includes the thin wall 68. The thin wall 68 is provided at a position where it faces the surface emitting laser element 20 in a plan view. The thin wall 68 is formed at the entire element side surface 23 facing the surface emitting laser element 20.

According to the above-described configuration, a distance between the thin wall 68 of the peripheral wall 60 close to the surface emitting laser element 20 and the surface emitting laser element 20 can be increased. As a result, it is possible to prevent the reflector 90 provided between the surface emitting laser element 20 and the peripheral wall 60 from climbing up onto the element front surface 21 to cover the element front surface 21 of the surface emitting laser element 20.

(2-7) The portion of the peripheral wall 60 close to the light receiving element 30 includes the thin wall 68. The thin wall 68 is provided at a position where it faces the light receiving element 30 in a plan view. The thin wall 68 is formed at the entire light receiving side surface 33 facing the light receiving element 30.

According to the above-described configuration, a distance between the thin wall 68 of the peripheral wall 60 close to the light receiving element 30 and the light receiving element 30 can be made large. As a result, it is possible to prevent the reflector 90 provided between the light receiving element 30 and the peripheral wall 60 from climbing up onto the light receiving front surface 31 to cover the light receiving front surface 31 of the light receiving element 30.

### Third Embodiment

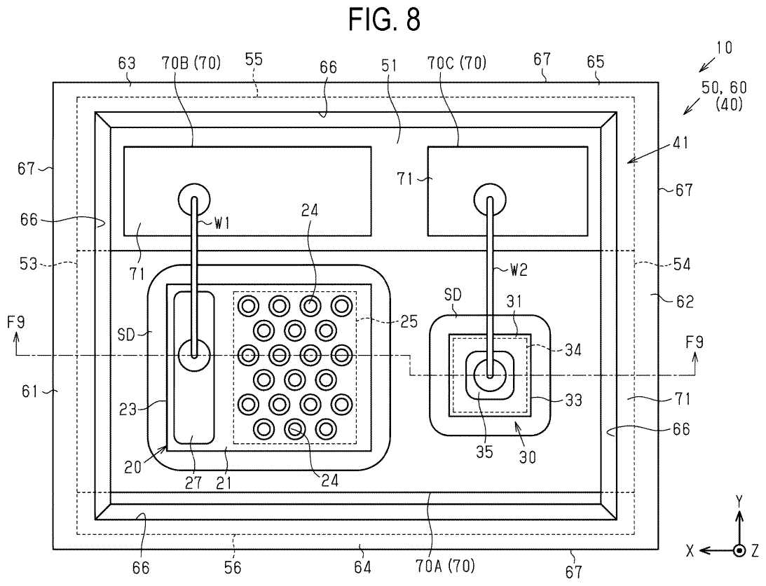

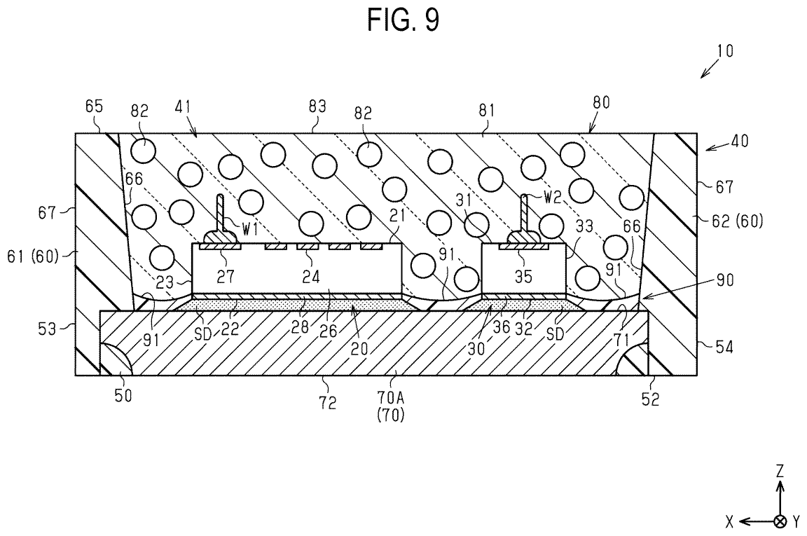

A semiconductor light emitting device 10 according to a third embodiment of the present disclosure will be described with reference to FIGS. 8 and 9. The semiconductor light emitting device 10 according to the third embodiment is mainly different from the semiconductor light emitting device 10 according to the first embodiment in terms of the configuration of the element container 40. The following describes the differences from the first embodiment. Meanwhile, the same constituent elements as in the first embodiment are denoted by the same reference numerals, and the explanation thereof will be omitted.

FIG. 8 shows a schematic planar structure of the semiconductor light emitting device 10 according to the third embodiment. In FIG. 8, both the diffusion layer 80 and the reflector 90 are omitted to facilitate understanding of the figure. FIG. 9 shows a schematic cross-sectional structure of the semiconductor light emitting device 10 taken along line F9-F9 in FIG. 8.

The bottom wall 50 and the peripheral wall 60 are separately formed in the element container 40 of the third embodiment. The bottom wall 50 is made of, for example, black epoxy resin. The bottom wall 50 is formed in a rectangular flat plate shape with the thickness direction being the Z direction. As in the first embodiment, the bottom wall 50 includes the bottom wall front surface 51, the bottom wall back surface 52, and the bottom wall side surfaces 53 to 56. As in the first embodiment, the bottom wall 50 is provided with the first to third terminals 70A to 70C.

The peripheral wall 60 is formed in a rectangular frame shape in a plan view. The peripheral wall 60 is bonded to an outer periphery of the bottom wall front surface 51 of the bottom wall 50 and to the bottom wall side surfaces 53 to 56. In an example, the peripheral wall 60 is bonded to the bottom wall 50 by an adhesive (not shown). The peripheral wall 60 is made of a reflective material having a higher light reflectivity than the diffusion layer 80. In an example, the peripheral wall 60 is made of a resin material having a higher light reflectivity than the diffusion layer 80. The peripheral wall 60 is made of a reflective material having a higher light reflectivity than the bottom wall 50. In an example, the peripheral wall 60 is made of a resin material having a higher light reflectivity than the bottom wall 50. In an example, the peripheral wall 60 is made of, for example, a white epoxy resin. For example, an epoxy resin mixed with titanium oxide or silica may be used as the white resin material.

The reflector 90 is provided so as to cover the entire bottom wall 50 in a plan view. Specifically, the reflector 90 is provided so as to cover a portion of the bottom wall front surface 51 of the bottom wall 50 which is surrounded by the peripheral wall 60, and the terminal front surfaces 71 of the first to third terminals 70A to 70C.

In the third embodiment, the front surface 91 of the reflector 90 is formed so as to be closer to the bottom wall front surface 51 than both the element front surface 21 of the surface emitting laser element 20 and the light receiving front surface 31 of the light receiving element 30 in the Z direction. In the example shown in FIG. 9, the reflector 90 partially covers both the element side surface 23 of the surface emitting laser element 20 and the light receiving side surface 33 of the light receiving element 30 in the Z direction. The reflector 90 partially covers the peripheral wall inner side surface 66 of the peripheral wall 60 in the Z direction.

The diffusion layer 80 provided over the reflector 90 partially covers both the element side surface 23 of the surface emitting laser element 20 and the light receiving side surface 33 of the light receiving element 30 in the Z direction. Further, the diffusion layer 80 partially covers the peripheral wall inner side surface 66 of the peripheral wall 60 in the Z direction.

### Effects of Third Embodiment

The semiconductor light emitting device 10 according to the third embodiment provides the following effects.

(3-1) The bottom wall 50 and the peripheral wall 60 in the element container 40 are separately provided. The reflector 90 covers the bottom wall 50. The peripheral wall 60 is made of a reflective material that has a higher light reflectivity than the diffusion layer 80.

According to the above-described configuration, when the laser light emitted from the element front surface 21 of the surface emitting laser element 20 is diffused by the diffusion layer 80, the laser light is directed toward the bottom wall 50 and the peripheral wall 60. Since the reflector 90 covers the bottom wall 50, the laser light that is diffused and then directed toward the bottom wall 50 is reflected by the reflector 90. Further, since the peripheral wall 60 is made of a reflective material, the laser light that is diffused and then directed toward the peripheral wall 60 is reflected by the peripheral wall 60. In this manner, since the laser light that is directed toward the bottom wall 50 and the peripheral wall 60 is reflected without being absorbed by the bottom wall 50 and the peripheral wall 60, the light output of the semiconductor light emitting device 10 can be improved.

### Fourth Embodiment

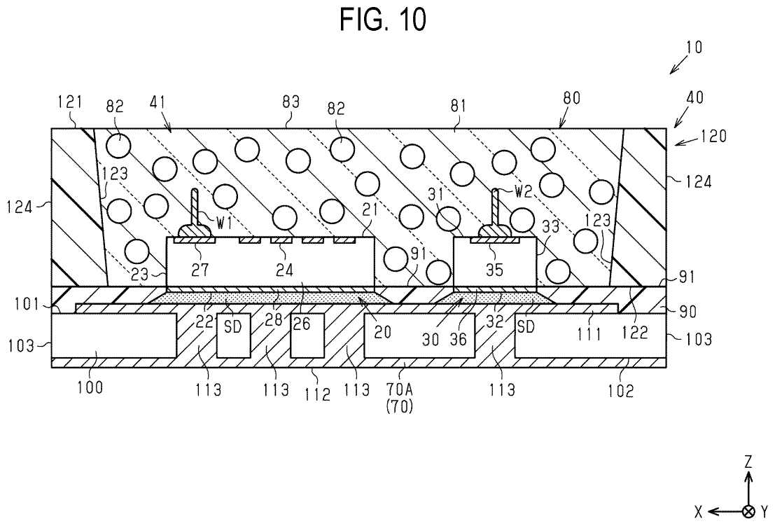

A semiconductor light emitting device 10 according to a fourth embodiment of the present disclosure will be described with reference to FIG. 10. The semiconductor light emitting device 10 according to the fourth embodiment is mainly different from the semiconductor light emitting device 10 according to the third embodiment in terms of a connection structure between the bottom wall 50 and the peripheral wall 60. The following describes the differences from the first embodiment. Meanwhile, the same constituent elements as those in the first embodiment are denoted by the same reference numerals, and the explanation thereof will be omitted. FIG. 10 shows a schematic cross-sectional structure of the semiconductor light emitting device 10. A cross-sectional position in FIG. 10 is the same as that in FIG. 9.

As shown in FIG. 10, the semiconductor light emitting device 10 includes a substrate 100 and a case 120 provided over the substrate 100. The substrate 100 and the case 120 constitute the element container 40.

The substrate 100 is formed in a rectangular flat plate shape with the thickness direction being the Z direction. The substrate 100 constitutes the bottom wall 50 of the element container 40. The substrate 100 is made of, for example, an insulating material. The substrate 100 is made of, for example, glass epoxy resin.

The substrate 100 includes a substrate front surface 101 and a substrate back surface 102 which face opposite sides from each other in the Z direction, and four substrate side surfaces 103 which connect the substrate front surface 101 and the substrate back surface 102. The substrate front surface 101 faces the same side as, for example, the element front surface 21 of the surface emitting laser element 20.

The semiconductor light emitting device 10 includes a plurality of front surface electrodes 111 formed at the substrate front surface 101, a plurality of back surface electrodes 112 formed at the substrate back surface 102, and a plurality of through-electrodes 113 which respectively and electrically connect the plurality of front surface electrodes 111 and the plurality of back surface electrodes 112.

The plurality of front surface electrodes 111 include first to third front surface electrodes. The first front surface electrode is a front surface electrode where the surface emitting laser element 20 and the light receiving element 30 are mounted. The second front surface electrode is a front surface electrode that is electrically connected to the surface emitting laser element 20. The third front surface electrode is a front surface electrode that is electrically connected to the light receiving element 30. Herein, the first front surface electrode corresponds to a portion of the first terminal 70A (see FIG. 2) of the first embodiment that is exposed from the bottom wall front surface 51. The second front surface electrode corresponds to a portion of the second terminal 70B (see FIG. 2) of the first embodiment that is exposed from the bottom wall front surface 51. The third front surface electrode corresponds to a portion of the third terminal 70C (see FIG. 2) of the first embodiment that is exposed from the bottom wall front surface 51. That is, the first front surface electrode is electrically connected to the back surface electrode 28 of the surface emitting laser element 20 and the back surface electrode 36 of the light receiving element 30 by a conductive bonding material SD. The second front surface electrode is electrically connected to the front surface electrode 27 of the surface emitting laser element 20 by the first wire W1. The third front surface electrode is electrically connected to the front surface electrode 35 of the light receiving element 30 by the second wire W2. In addition, in an example, the first front surface electrode has the same arrangement position and shape as the terminal front surface 71 (see FIG. 2) of the first terminal 70A in a plan view. The second front surface electrode has the same arrangement position and shape as the terminal front surface 71 of the second terminal 70B in a plan view. The third front surface electrode has the same arrangement position and shape as the terminal front surface 71 of the third terminal 70C in a plan view.

The plurality of back surface electrodes 112 include first to third back surface electrodes. In an example, the first back surface electrode corresponds to a portion of the first terminal 70A of the first embodiment that is exposed from the bottom wall back surface 52. The second back surface electrode corresponds to a portion of the second terminal 70B of the first embodiment that is exposed from the bottom wall back surface 52. The third front surface electrode corresponds to a portion of the third terminal 70C of the first embodiment that is exposed from the bottom wall back surface 52. Further, in an example, the first back surface electrode has the same arrangement position and shape as the terminal back surface 72 of the first terminal 70A in a plan view. The second back surface electrode has the same arrangement position and shape as the terminal back surface 72 of the second terminal 70B in a plan view. The third front surface electrode has the same arrangement position and shape as the terminal back surface 72 of the third terminal 70C in a plan view.

Each of the plurality of through-electrodes 113 passes through the substrate 100 in the Z direction. The plurality of through-electrodes 113 include first to third through-electrodes. The first through-electrode electrically connects the first front surface electrode and the first back surface electrode. The second through-electrode electrically connects the second front surface electrode and the second back surface electrode. The third through-electrode electrically connects the third front surface electrode and the third back surface electrode.

The reflector 90 is provided over the substrate front surface 101 of the substrate 100. The reflector 90 is formed at the entire substrate front surface 101. The reflector 90 covers the plurality of front surface electrodes 111. In an example, the front surface 91 of the reflector 90 is formed to be closer to the bottom wall front surface 51 than both the element front surface 21 of the surface emitting laser element 20 and the light receiving front surface 31 of the light receiving element 30 in the Z direction. In the example shown in FIG. 10, the reflector 90 partially covers both the element side surface 23 of the surface emitting laser element 20 and the light receiving side surface 33 of the light receiving element 30 in the Z direction. The reflector 90 partially covers the peripheral wall inner side surface 66 of the peripheral wall 60 in the Z direction.

The case 120 is arranged over the reflector 90. In the fourth embodiment, the substrate 100 and the case 120 are bonded to each other via the reflector 90. In this manner, the reflector 90 also functions as a bonding material for bonding the substrate 100 and the case 120.

The case 120 is formed in a rectangular frame shape in a plan view. The case 120 constitutes the peripheral wall 60 of the element container 40. The case 120 is made of, for example, a resin material having a higher reflectivity than the substrate 100. In an example, the case 120 is made of a white resin material. The case 120 is arranged over the reflector 90.

The case 120 includes a case front surface 121 and a case back surface 122 which face opposite sides from each other in the Z direction. The case front surface 121 faces the same side as the substrate front surface 101, and the case back surface 122 faces the same side as the substrate back surface 102. The case back surface 122 is in contact with the front surface 91 of the reflector 90. In an example, the entire case back surface 122 is in contact with the front surface 91 of the reflector 90.

The case 120 includes a case inner side surface 123 and a case outer side surface 124. The case inner side surface 123 is formed as an inclined surface that is inclined toward the case outer side surface 124 from the case back surface 122 toward the case front surface 121. The case outer side surface 124 is formed as a flat surface along the Z direction.

The diffusion layer 80 is provided over the reflector 90. The diffusion layer 80 covers the entire case inner side surface 123 of the case 120. The diffusion layer 80 partially covers both the element side surface 23 of the surface emitting laser element 20 and the light receiving side surface 33 of the light receiving element 30 in the Z direction. The diffusion layer 80 covers the entire case inner side surface 123 of the case 120.

### Effects of Fourth Embodiment

The semiconductor light emitting device 10 according to the fourth embodiment of the present disclosure provides the following effects.

(4-1) The reflector 90 covers the substrate 100 constituting the bottom wall 50. The case 120 constituting the peripheral wall 60 is provided over the reflector 90.

According to the above-described configuration, the reflector 90 can bond the substrate 100 and the case 120 constituting the bottom wall 50. In addition, the reflector 90 can reflect laser light emitted from the element front surface 21 of the surface emitting laser element 20, diffused by the diffusion layer 80, and then directed toward the substrate 100. Further, the reflector 90 fills a gap between the substrate 100 and the case 120, and therefore can prevent light from leaking between the substrate 100 and the case 120.

### Modifications

Each of the above-described embodiments can be modified and implemented as follows. Further, the following modifications can be implemented in combination with each other unless technically contradictory.

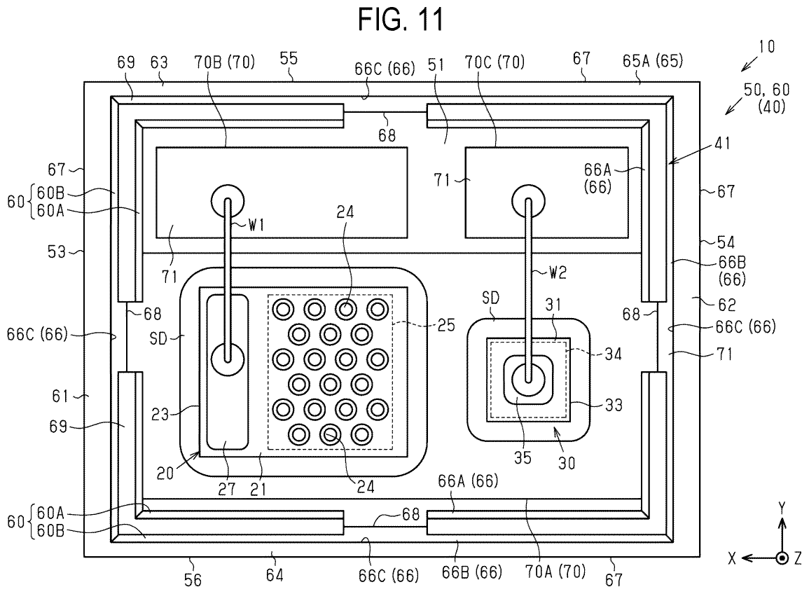

In the second embodiment, the number and arrangement positions of the thin walls 68 of the peripheral wall 60 may be changed arbitrarily. In an example, as shown in FIG. 11, one thin wall 68 may be provided at each of the side walls 61 to 64 of the peripheral wall 60. The thin wall 68 of the side wall 61 is arranged at a position overlapping the surface emitting laser element 20 when viewed from the X direction. In the example shown in FIG. 11, a dimension of the thin wall 68 in the Y direction is smaller than a dimension of the surface emitting laser element 20 in the Y direction. The thin wall 68 of the side wall 62 is arranged at a position overlapping the light receiving element 30 when viewed from the X direction. In the example shown in FIG. 11, the dimension of the thin wall 68 in the Y direction is smaller than a dimension of the light receiving element 30 in the Y direction. The thin walls 68 of the side walls 63 and 64 are arranged at positions overlapping the surface emitting laser element 20 when viewed from the Y direction. Dimensions of these thin walls 68 in the X direction are smaller than a dimension of the surface emitting laser element 20 in the X direction.

In the second embodiment, a size of the thin wall 68 of the peripheral wall 60 in a plan view may be changed arbitrarily. In an example, a size of the thin wall 68 of the side wall 61 in the peripheral wall 60 in the Y direction may be larger than a size of the surface emitting laser element 20 in the Y direction. In an example, the size of the thin wall 68 of the side wall 61 in the peripheral wall 60 in the Y direction may be smaller than the size of the surface emitting laser element 20 in the Y direction. In another example, a size of the thin wall 68 of the side wall 64 in the peripheral wall 60 in the X direction may be larger than a size of the surface emitting laser element 20 in the X direction. In an example, the size of the thin wall 68 of the side wall 64 in the peripheral wall 60 in the X direction may be smaller than the size of the surface emitting laser element 20 in the X direction. In another example, a size of the thin wall 68 of the side wall 62 in the peripheral wall 60 in the Y direction may be larger than a size of the light receiving element 30 in the Y direction. In an example, the size of the thin wall 68 of the side wall 62 in the peripheral wall 60 in the Y direction may be smaller than the size of the light receiving element 30 in the Y direction. Further, in an example, the size of the thin wall 68 of the side wall 64 in the peripheral wall 60 in the X direction may be larger than a size of the light receiving element 30 in the X direction. In an example, the size of the thin wall 68 of the side wall 64 in the peripheral wall 60 in the X direction may be smaller than the size of the light receiving element 30 in the X direction.

In the second embodiment, at least one of the plurality of thin walls 68 of the peripheral wall 60 may be omitted. In an example, the thin wall 68 corresponding to the side wall 61 may be omitted. In an example, the thin wall 68 corresponding to the surface emitting laser element 20 in the side wall 64 may be omitted. In an example, two thin walls 68 facing the surface emitting laser element 20 in a plan view may be omitted. In an example, the thin wall 68 corresponding to the side wall 62 may be omitted. In an example, the thin wall 68 corresponding to the light receiving element 30 in the side wall 64 may be omitted. In an example, two thin walls 68 facing the light receiving element 30 in a plan view may be omitted.

In the second embodiment, the step 69 in the peripheral wall 60 may be omitted. That is, the peripheral wall 60 may have the configuration of the first embodiment and include the thin wall 68.

In the second embodiment, a formation range of the reflector 90 in the peripheral wall 60 may be changed arbitrarily. In an example, the reflector 90 may be configured to cover the peripheral wall inner side surface 66A of the first peripheral wall 60A of the peripheral wall 60, but not to cover the step 69. In this case, the step 69 and the peripheral wall inner side surface 66B of the second peripheral wall 60B are covered by, for example, the diffusion layer 80. Further, in an example, the reflector 90 may be configured to cover the peripheral wall inner side surface 66A of the first peripheral wall 60A of the peripheral wall 60 and the step 69, but not to cover the peripheral wall inner side surface 66B of the second peripheral wall 60B. In this case, the peripheral wall inner side surface 66B of the second peripheral wall 60B is covered by, for example, the diffusion layer 80.

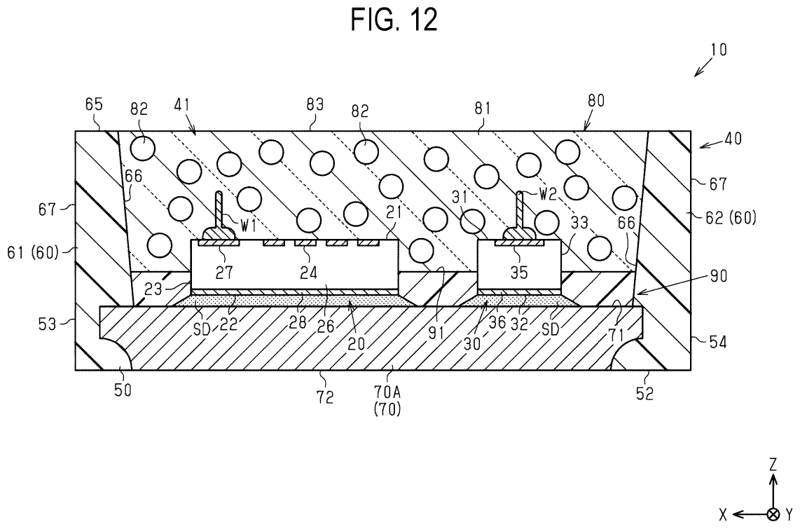

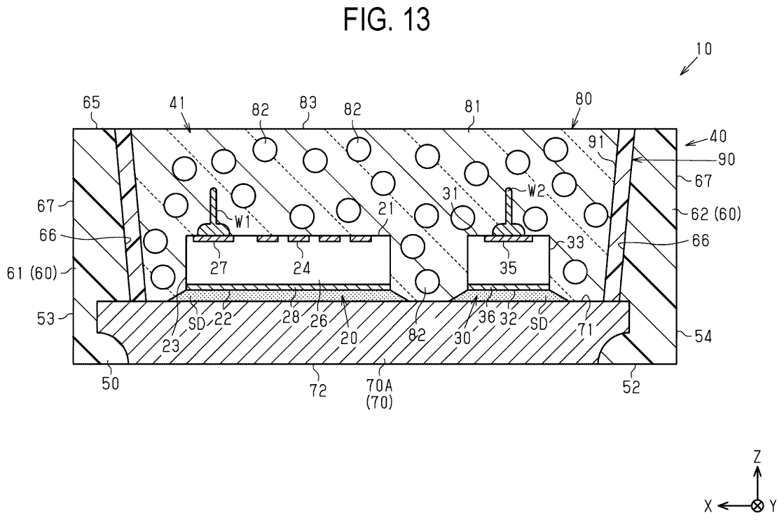

In the first and second embodiments, a formation range of the reflector 90 may be changed arbitrarily. For example, the reflector 90 may be changed as in a first modification shown in FIG. 12 and a second modification shown in FIG. 13.

As shown in FIG. 12, in a semiconductor light emitting device 10 according to the first modification, the reflector 90 may be provided so as to cover the bottom wall 50 without covering the peripheral wall 60. As shown in FIG. 13, in a semiconductor light emitting device 10 according to the second modification, the reflector 90 may be provided so as to cover the peripheral wall 60 without covering the bottom wall 50.

In each embodiment, the reflector 90 may be formed so as not to cover the element side surface 23 of the surface emitting laser element 20. In an example, the reflector 90 may be formed so as to cover the conductive bonding material SD without covering the element side surface 23. In this case, the reflector 90 may cover the bottom wall front surface 51 of the bottom wall 50 and the terminal front surfaces 71 of the first to third terminals 70A to 70C.

In each embodiment, the reflector 90 may be formed so as not to cover the light receiving side surface 33 of the light receiving element 30. In an example, the reflector 90 may be formed so as to cover the conductive bonding material SD without covering the light receiving side surface 33. In this case, the reflector 90 may cover the bottom wall front surface 51 of the bottom wall 50 and the terminal front surfaces 71 of the first to third terminals 70A to 70C.

In the third embodiment, the bottom wall 50 may be made of a resin material having a higher light reflectivity than the diffusion layer 80.

In the third embodiment, the reflector 90 covering the bottom wall 50 may be omitted. In this case, the peripheral wall 60 constitutes the reflector.

In the fourth embodiment, the case 120 may be made of, for example, black epoxy resin.

In the fourth embodiment, first to third front surface electrodes may be formed at the substrate front surface 101 of the substrate 100. In other words, external electrodes may not be formed at the substrate back surface 102 of the substrate 100. The first front surface electrode is an electrode where the surface emitting laser element 20 and the light receiving element 30 are mounted. The second front surface electrode is an electrode electrically connected to the surface emitting laser element 20. The third front surface electrode is an electrode electrically connected to the light receiving element 30. That is, the first front surface electrode corresponds to the first terminal 70A, the second front surface electrode corresponds to the second terminal 70B, and the third front surface electrode corresponds to the third terminal 70C.

In each embodiment, the element front surface 21 of the surface emitting laser element 20 and the light receiving front surface 31 of the light receiving element 30 may be arranged at different positions in the Z direction. In an example, the light receiving front surface 31 of the light receiving element 30 may be located to be closer to the bottom wall 50 than the element front surface 21 of the surface emitting laser element 20. In an example, the element front surface 21 of the surface emitting laser element 20 may be located to be closer to the bottom wall 50 than the light receiving front surface 31 of the light receiving element 30.

In each embodiment, the configuration of the plurality of terminals 70 may be changed arbitrarily. In an example, the plurality of terminals 70 may include first to fourth terminals. The first terminal is a terminal where the surface emitting laser element 20 is mounted. The first terminal is electrically connected to the back surface electrode 28 of the surface emitting laser element 20. The second terminal is a terminal where the light receiving element 30 is mounted. The second terminal is electrically connected to the back surface electrode 36 of the light receiving element 30. The third terminal is a terminal electrically connected to the front surface electrode 27 of the surface emitting laser element 20 via the first wire W1. The fourth terminal is a terminal electrically connected to the front surface electrode 35 of the light receiving element 30 via the second wire W2. In another example, the plurality of terminals 70 may include a first terminal where the surface emitting laser element 20 is mounted, a second terminal where the light receiving element 30 is mounted, and a third terminal to which both the first wire W1 and the second wire W2 are connected.

In each embodiment, the reflector 90 may be made of a resin material of a color other than white, as long as the reflector 90 has a higher light reflectivity than the diffusion layer 80.

In each embodiment, the diffusion layer 80 may partially cover the light emitting region 25 of the surface emitting laser element 20.

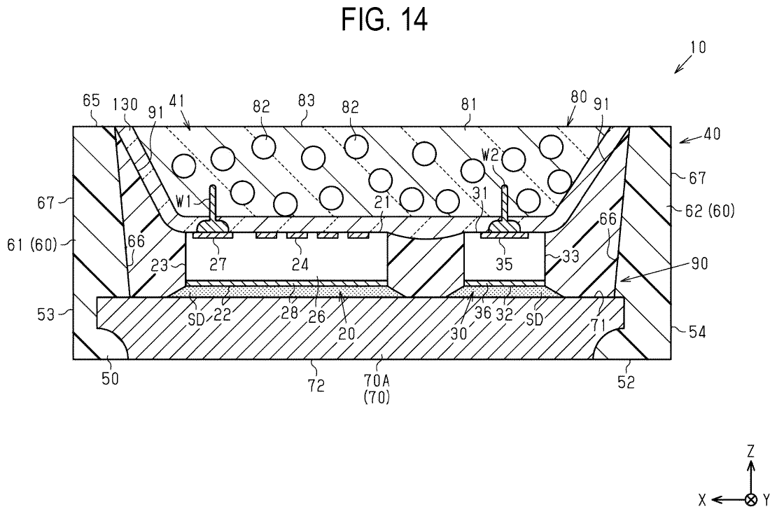

In each embodiment, as shown in FIG. 14, a transparent resin layer 130 may be interposed between the reflector 90 and the diffusion layer 80. In the example shown in FIG. 14, the resin layer 130 is formed at the entire front surface 91 of the reflector 90. The resin layer 130 may be made of, for example, a transparent epoxy resin. A formation range of the resin layer 130 may be changed arbitrarily. In an example, the resin layer 130 may be selectively formed at the front surface 91 of the reflector 90.

In each embodiment, a formation range of the diffusion layer 80 may be changed arbitrarily. In an example, the diffusion layer 80 may cover at least the light emitting region 25 of the element front surface 21 of the surface emitting laser element 20. For this reason, for example, the diffusion layer 80 may be configured to cover the element front surface 21 of the surface emitting laser element 20 while not covering the light receiving front surface 31 of the light receiving element 30. In this case, the light receiving front surface 31 may be exposed, for example, or may be covered by a transparent resin layer.

In each embodiment, the shape of the front surface 91 of the reflector 90 is not limited to a curved concave shape, and may be changed arbitrarily. In an example, the front surface 91 of the reflector 90 provided between the surface emitting laser element 20 and the light receiving element 30 may include a flat surface perpendicular to the Z direction. Further, in an example, the front surface 91 of the reflector 90 may include a flat inclined surface directed toward the peripheral wall front surface 65 from the surface emitting laser element 20 toward the peripheral wall 60. Further, in an example, the front surface 91 of the reflector 90 may include a flat inclined surface directed toward the peripheral wall front surface 65 from the light receiving element 30 toward the peripheral wall 60.

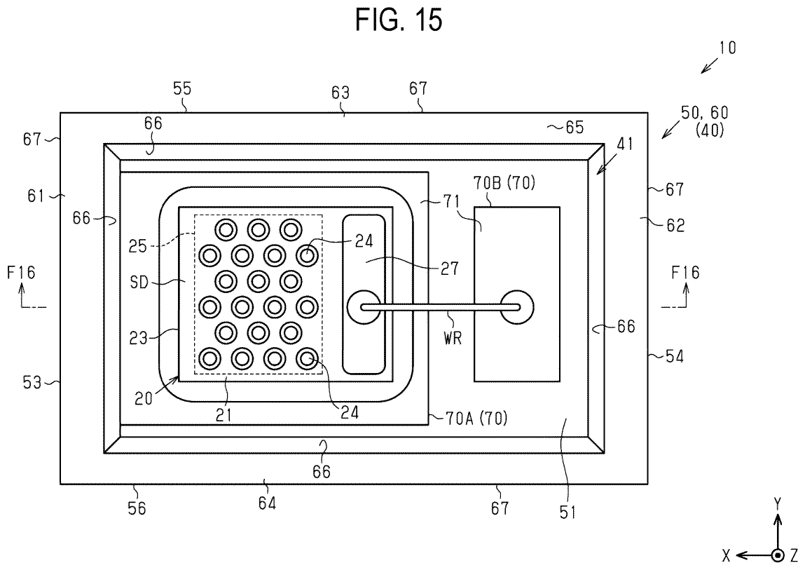

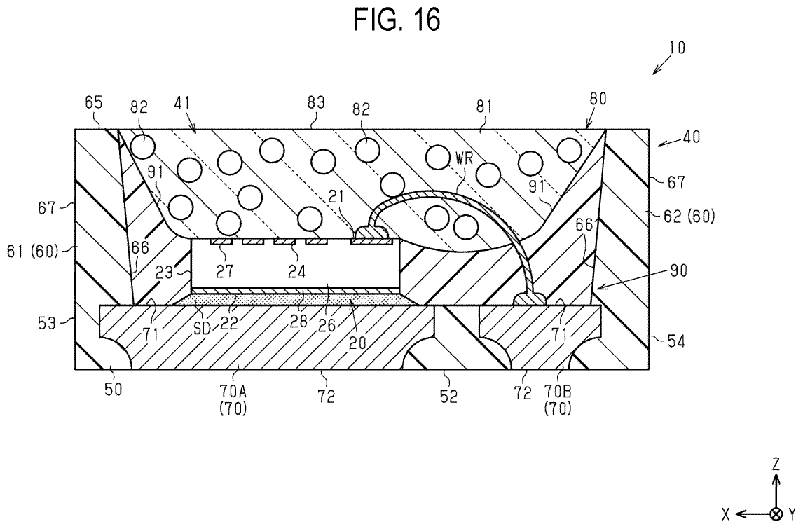

In each embodiment, the light receiving element 30 may be omitted from the semiconductor light emitting device 10. FIGS. 15 and 16 show a configuration in which the light receiving element 30 is omitted from the semiconductor light emitting device 10 of the first embodiment. FIG. 15 shows a schematic planar structure of a semiconductor light emitting device 10 according to a modification. In FIG. 15, the diffusion layer 80 and the reflector 90 are omitted in order to facilitate understanding of the figure. FIG. 16 shows a schematic cross-sectional structure of the semiconductor light emitting device 10 according to the modification taken along line F16-F16 in FIG. 15.

As shown in FIG. 15, the containing space 41 of the element container 40 contains the surface emitting laser element 20. The element container 40 includes a first terminal 70A and a second terminal 70B as a plurality of terminals. The surface emitting laser element 20 is mounted on the first terminal 70A. Mounting shapes of the surface emitting laser element 20 and the first terminal 70A are the same as in the first embodiment. Therefore, the back surface electrode 28 of the surface emitting laser element 20 is electrically connected to the first terminal 70A. The second terminal 70B is electrically connected to the surface emitting laser element 20. The front surface electrode 27 of the surface emitting laser element 20 and the second terminal 70B are electrically connected to each other by a wire WR. In the example shown in FIG. 15, the wire WR extends along the X direction in a plan view.

As shown in FIG. 16, the reflector 90 covers the bottom wall front surface 51 of the bottom wall 50 and the peripheral wall inner side surface 66 of the peripheral wall 60 of the element container 40. The front surface 91 of the reflector 90 includes a curved concave shape formed so as to extend toward the peripheral wall front surface 65 as the front surface 91 extends from the surface emitting laser element 20 to the peripheral wall 60. The diffusion layer 80 covers the element front surface 21 of the surface emitting laser element 20 and is provided over the reflector 90. The semiconductor light emitting device 10 of the modification shown in FIGS. 15 and 16 can be obtained by combining the configurations of the second to fourth embodiments.

One or more of the various examples described in the present disclosure can be combined unless technically contradictory. The term “over” as used herein includes meanings of “on” and “above” unless clearly stated otherwise in the context. Therefore, for example, an expression “a first element is arranged over a second element” is intended to mean that in some embodiments, the first element can be directly arranged on the second element in contact with the second element, while in other embodiments, the first element can be arranged above the second element without contacting the second element. That is, the term “over” does not exclude a structure in which other elements are formed between the first element and the second element.

The Z direction used herein does not necessarily have to be the vertical direction, and it does not have to be exactly the same as the vertical direction. Therefore, various structures according to the present disclosure are not limited to “up” and “down” in the Z direction described herein as being “up” and “down” in the vertical direction. For example, the X direction may be the vertical direction, or the Y direction may be the vertical direction.

### Supplementary Notes

The technical ideas which can be understood from the present disclosure are described below. In addition, for the purpose of aiding understanding rather than limitation, constituent elements described in supplementary notes are labeled with reference numerals of the corresponding constituent elements in the above-described embodiments. The reference numerals are provided as examples to aid in understanding, and the constituent elements described in supplementary notes should not be limited to the constituent elements indicated by the reference numerals.

### Supplementary Note 1

A semiconductor light emitting device (10) including:
a surface emitting laser element (20) which includes an element front surface (21) and is configured to emit laser light from the element front surface (21);
an element container (40) which includes a bottom wall (50) where the surface emitting laser element (20) is arranged and a peripheral wall (60) surrounding the surface emitting laser element (20) when viewed from a direction (Z direction) perpendicular to the element front surface (21), the bottom wall (50) and the peripheral wall (60) constituting a containing space (41) which contains the surface emitting laser element (20) and is open on a same side as the element front surface (21);
a diffusion layer (80) which covers the element front surface (21) in the containing space (41) and includes a diffusion material (82); and
a reflector (90) which covers at least one selected from the group of the bottom wall (50) and the peripheral wall (60) in the containing space (41) and is made of a resin material having a higher reflectivity than the diffusion layer (80),
wherein the reflector (90) is configured to reflect the laser light emitted from the element front surface (21) and diffused by the diffusion material (82).

### Supplementary Note 2

The semiconductor light emitting device of Supplementary Note 1, wherein the reflector (90) covers both the bottom wall (50) and the peripheral wall (60).

### Supplementary Note 3

The semiconductor light emitting device of Supplementary Note 2, wherein the peripheral wall (60) includes a peripheral wall front surface (65) which faces the same side as the element front surface (21) and is provided at a position farther from the bottom wall (50) than the element front surface (21), and
wherein a front surface (91) of the reflector (90) includes a curved concave shape formed so as to extend toward the peripheral wall front surface (65) as the front surface (91) of the reflector (90) extends from the surface emitting laser element (20) to the peripheral wall (60).

### Supplementary Note 4

The semiconductor light emitting device of any one of Supplementary Notes 1 to 3, wherein the surface emitting laser element (20) includes:
an element back surface (22) which faces an opposite side from the element front surface (21); and
an element side surface (23) connecting the element front surface (21) and the element back surface (22),
wherein the reflector (90) covers the element side surface (23).

### Supplementary Note 5

The semiconductor light emitting device of any one of Supplementary Notes 1 to 4, wherein the surface emitting laser element (20) includes a light emitting region (25) formed at the element front surface (21), and
wherein the diffusion layer (80) entirely covers the light emitting region (25) when viewed from the direction (Z direction) perpendicular to the element front surface (21).

### Supplementary Note 6

The semiconductor light emitting device of Supplementary Note 5, wherein the diffusion layer (80) covers the element front surface (21) in a state where the diffusion layer (80) is in contact with the element front surface (21).

### Supplementary Note 7

The semiconductor light emitting device of any one of Supplementary Notes 1 to 6, wherein the surface emitting laser element (20) is arranged to be close to a portion of the peripheral wall (60), and
wherein the portion of the peripheral wall (60) close to the surface emitting laser element (20) includes a portion (68) having a thickness that is smaller than a thickness of a portion of the peripheral wall (60) farther from the surface emitting laser element (20) than the portion of the peripheral wall (60) close to the surface emitting laser element (20).

### Supplementary Note 8

The semiconductor light emitting device of any one of Supplementary Notes 1 to 7, wherein the peripheral wall (60) includes:
a first peripheral wall (60A) which is close to the bottom wall (50) in the direction (Z direction) perpendicular to the element front surface (21);
a second peripheral wall (60B) which is located on an opposite side of the first peripheral wall (60A) from the bottom wall (50) in the direction (Z direction) perpendicular to the element front surface (21) and has a thickness smaller than a thickness of the first peripheral wall (60A); and
a step (69) which is formed by the first peripheral wall (60A) and the second peripheral wall (60B),
wherein the step (69) is located at a same position as the element front surface (21) or located to be closer to the bottom wall (50) than the element front surface (21) in the direction (Z direction) perpendicular to the element front surface (21).

### Supplementary Note 9

The semiconductor light emitting device of Supplementary Note 8, wherein the reflector (90) covers the step (69).

### Supplementary Note 10

The semiconductor light emitting device of Supplementary Note 8 or 9, wherein the reflector (90) covers an inner side surface (66B) constituting the second peripheral wall (60B).

### Supplementary Note 11

The semiconductor light emitting device of any one of Supplementary Notes 1 to 10, wherein the reflector (90) is made of a white resin material.

### Supplementary Note 12

The semiconductor light emitting device of any one of Supplementary Notes 1 to 11, wherein the bottom wall (50) and the peripheral wall (60) are separately provided, wherein the reflector (90) covers the bottom wall (50), and
wherein the peripheral wall (60) is made of a reflective material having a higher light reflectivity than the diffusion layer (80).

### Supplementary Note 13

The semiconductor light emitting device of Supplementary Note 12, wherein the peripheral wall (60/120) is arranged over the reflector (90).

### Supplementary Note 14

The semiconductor light emitting device of any one of Supplementary Notes 1 to 13, further including a light receiving element (30) which is arranged at the bottom wall (50) in the containing space (41),
wherein the light receiving element (30) is configured to receive the laser light emitted from the element front surface (21) of the surface emitting laser element (20) and diffused by the diffusion material (82).

### Supplementary Note 15

The semiconductor light emitting device of Supplementary Note 14, wherein the light receiving element (30) includes:
a light receiving front surface (31) which faces the same side as the element front surface (21) and includes a light receiving region (34) where the laser light is received;
a light receiving back surface (32) which faces an opposite side from the light receiving front surface (31); and
a light receiving side surface (33) connecting the light receiving front surface (31) and the light receiving back surface (32),
wherein the reflector (90) covers the light receiving side surface (33).

### Supplementary Note 16

The semiconductor light emitting device of Supplementary Note 15, wherein the reflector (90) is provided between the surface emitting laser element (20) and the light receiving element (30), and
wherein a front surface (91) of the reflector (90) provided between the surface emitting laser element (20) and the light receiving element (30) includes a curved concave shape.

### Supplementary Note 17

The semiconductor light emitting device of Supplementary Note 15 or 16, wherein the element front surface (21) of the surface emitting laser element (20) and the light receiving front surface (31) of the light receiving element (30) are at a same position in the direction (Z direction) perpendicular to the element front surface (21).

### Supplementary Note 18

The semiconductor light emitting device of any one of Supplementary Notes 14 to 17, wherein the light receiving element (30) is arranged to be close to a portion of the peripheral wall (60), and
wherein the portion of the peripheral wall (60) close to the light receiving element (30) includes a portion having a thickness that is smaller than a thickness of a portion of the peripheral wall (60) farther from the light receiving element (30) than the portion of the peripheral wall (60) close to the light receiving element (30).

### Supplementary Note 19

The semiconductor light emitting device of any one of Supplementary Notes 1 to 18, wherein the element container (40) includes a terminal (70) provided to penetrate the bottom wall (50), and
wherein the terminal (70) includes:
a terminal front surface (71) where the surface emitting laser element (20) is mounted; and
a terminal back surface (72) which faces an opposite side from the terminal front surface (71) and is exposed from the bottom wall (50).

The above description is merely an example. Those skilled in the art will appreciate that more combinations and substitutions are possible beyond the constituent elements and methods (manufacturing processes) listed for the purposes of illustrating the techniques of the present disclosure. The present disclosure is intended to cover all alternatives, modifications, and changes that fall within the scope of the present disclosure, including the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor light emitting device comprising:
a surface emitting laser element which includes an element front surface and is configured to emit laser light from the element front surface;
an element container which includes a bottom wall where the surface emitting laser element is arranged and a peripheral wall surrounding the surface emitting laser element when viewed from a direction perpendicular to the element front surface, the bottom wall and the peripheral wall constituting a containing space which contains the surface emitting laser element and is open on a same side as the element front surface;
a diffusion layer which covers the element front surface in the containing space and includes a diffusion material; and
a reflector which covers at least one selected from the group of the bottom wall and the peripheral wall in the containing space and is made of a resin material having a higher reflectivity than the diffusion layer,
wherein the reflector is configured to reflect the laser light emitted from the element front surface and diffused by the diffusion material.

2. The semiconductor light emitting device of claim 1, wherein the reflector covers both the bottom wall and the peripheral wall.

3. The semiconductor light emitting device of claim 2, wherein the peripheral wall includes a peripheral wall front surface which faces the same side as the element front surface and is provided at a position farther from the bottom wall than the element front surface, and
wherein a front surface of the reflector includes a curved concave shape formed so as to extend toward the peripheral wall front surface as the front surface of the reflector extends from the surface emitting laser element to the peripheral wall.

4. The semiconductor light emitting device of claim 1, wherein the surface emitting laser element includes:
an element back surface which faces an opposite side from the element front surface; and
an element side surface connecting the element front surface and the element back surface, and
wherein the reflector covers the element side surface.

5. The semiconductor light emitting device of claim 1, wherein the surface emitting laser element includes a light emitting region formed at the element front surface, and
wherein the diffusion layer entirely covers the light emitting region when viewed from the direction perpendicular to the element front surface.

6. The semiconductor light emitting device of claim 5, wherein the diffusion layer covers the element front surface in a state where the diffusion layer is in contact with the element front surface.

7. The semiconductor light emitting device of claim 1, wherein the surface emitting laser element is arranged to be close to a portion of the peripheral wall, and
wherein the portion of the peripheral wall close to the surface emitting laser element includes a portion having a thickness that is smaller than a thickness of a portion of the peripheral wall farther from the surface emitting laser element than the portion of the peripheral wall close to the surface emitting laser element.

8. The semiconductor light emitting device of claim 1, wherein the peripheral wall includes:
a first peripheral wall which is close to the bottom wall in the direction perpendicular to the element front surface;
a second peripheral wall which is located on an opposite side of the first peripheral wall from the bottom wall in the direction perpendicular to the element front surface and has a thickness smaller than a thickness of the first peripheral wall; and
a step which is formed by the first peripheral wall and the second peripheral wall, and
wherein the step is located at a same position as the element front surface or located to be closer to the bottom wall than the element front surface in the direction perpendicular to the element front surface.

9. The semiconductor light emitting device of claim 8, wherein the reflector covers the step.

10. The semiconductor light emitting device of claim 8, wherein the reflector covers an inner side surface constituting the second peripheral wall.

11. The semiconductor light emitting device of claim 1, wherein the reflector is made of a white resin material.

12. The semiconductor light emitting device of claim 1, wherein the bottom wall and the peripheral wall are separately provided,
wherein the reflector covers the bottom wall, and
wherein the peripheral wall is made of a reflective material having a higher light reflectivity than the diffusion layer.

13. The semiconductor light emitting device of claim 12, wherein the peripheral wall is arranged over the reflector.

14. The semiconductor light emitting device of claim 1, further comprising a light receiving element which is arranged at the bottom wall in the containing space,
wherein the light receiving element is configured to receive the laser light emitted from the element front surface of the surface emitting laser element and diffused by the diffusion material.

15. The semiconductor light emitting device of claim 14, wherein the light receiving element includes:
a light receiving front surface which faces the same side as the element front surface and includes a light receiving region where the laser light is received;
a light receiving back surface which faces an opposite side from the light receiving front surface; and
a light receiving side surface connecting the light receiving front surface and the light receiving back surface, and
wherein the reflector covers the light receiving side surface.

16. The semiconductor light emitting device of claim 15, wherein the reflector is provided between the surface emitting laser element and the light receiving element, and
wherein a front surface of the reflector provided between the surface emitting laser element and the light receiving element includes a curved concave shape.

17. The semiconductor light emitting device of claim 15, wherein the element front surface of the surface emitting laser element and the light receiving front surface of the light receiving element are at a same position in the direction perpendicular to the element front surface.

18. The semiconductor light emitting device of claim 14, wherein the light receiving element is arranged to be close to a portion of the peripheral wall, and
wherein the portion of the peripheral wall close to the light receiving element includes a portion having a thickness that is smaller than a thickness of a portion of the peripheral wall farther from the light receiving element than the portion of the peripheral wall close to the light receiving element.

19. The semiconductor light emitting device of claim 1, wherein the element container includes a terminal provided to penetrate the bottom wall, and
wherein the terminal includes:
a terminal front surface where the surface emitting laser element is mounted; and
a terminal back surface which faces an opposite side from the terminal front surface and is exposed from the bottom wall.
